(19) United States
(12) Patent Application Publication
(10) Pub. No.: US 2024/0014267 A1
(43) Pub. Date: Jan. 11, 2024

(54) SEMICONDUCTOR DEVICE

(71) Applicant: ROHM CO., LTD., Kyoto-shi (JP)

(72) Inventor: Takayuki OSAWA, Kyoto-shi (JP)

(73) Assignee: ROHM CO., LTD., Kyoto-shi (JP)

(21) Appl. No.: 18/472,320

(22) Filed: Sep. 22, 2023

Related U.S. Application Data
(63) Continuation of application No. PCT/JP2022/007771, filed on Feb. 25, 2022.

(30) Foreign Application Priority Data
Mar. 26, 2021 (JP) 2021-053946

(51) Int. Cl. H01L 29/06; H01L 29/739

(52) U.S. Cl. CPC H01L 29/0696; H01L 29/7393

(57) ABSTRACT

A semiconductor device comprises: a cell region and a peripheral region. The cell region includes an insulation film covering cells, and an electrode portion including a stacked part stacked on the insulation film. The peripheral region includes a first semiconductor layer of a first conductive type, a second semiconductor region of a second conductivity type, a peripheral insulation film, a peripheral electrode portion, a barrier layer, and a passivation film. The barrier layer covers both the peripheral insulation film and the peripheral electrode portion and has a smaller diffusion coefficient than the peripheral insulation film. The passivation film stacks on the barrier layer and has a larger diffusion coefficient than the barrier layer. The peripheral electrode portion includes a projection. A thickness of the projection is less than a thickness of the stacked part.

### CROSS-REFERENCE TO RELATED APPLICATIONS

This application is a continuation of International Application No. PCT/JP2022/007771, filed Feb. 25, 2022, which claims priority to JP 2021-053946, filed Mar. 26, 2021, the entire contents of each are incorporated herein by reference.

### BACKGROUND

The present disclosure relates to a semiconductor device.

In a semiconductor device such as an insulated gate bipolar transistor (IGBT) for use in, for example, a vehicle inverter device, a protective film is formed on an electrode (refer to, for example, Japanese Laid-Open Patent Publication No. 2020-136472).

### BRIEF DESCRIPTION OF DRAWINGS

FIG. 1 is a plan view showing a semiconductor device of a first embodiment.

FIG. 2 is a plan view showing the semiconductor device of FIG. 1 without a protective film.

FIG. 3 is a cross-sectional view illustrating the cross-sectional structure of a cell region in one example.

FIG. 4 is a cross-sectional view illustrating the cross section of the semiconductor device taken along line 4-4 in FIG. 1.

FIG. 5 is a partially enlarged view of an FLR in a peripheral region of FIG. 4.

FIG. 6 is an enlarged view of a gate finger and an emitter extension in the peripheral region of FIG. 4.

FIG. 7 is an enlarged view of an equipotential ring in the peripheral region of FIG. 4.

FIG. 8 is a diagram illustrating one example of a manufacturing step in a method for manufacturing the semiconductor device of the first embodiment.

FIG. 9 is a diagram illustrating one example of a manufacturing step in a method for manufacturing the semiconductor device.

FIG. 10 is a diagram illustrating one example of a manufacturing step in the method for manufacturing the semiconductor device.

FIG. 11 is a diagram illustrating one example of a manufacturing step in the method for manufacturing the semiconductor device.

FIG. 12 is a diagram illustrating one example of a manufacturing step in the method for manufacturing the semiconductor device.

FIG. 13 is a diagram illustrating one example of a manufacturing step in the method for manufacturing the semiconductor device.

FIG. 14 is a diagram illustrating one example of a manufacturing step in the method for manufacturing the semiconductor device.

FIG. 15 is a diagram illustrating one example of a manufacturing step in the method for manufacturing the semiconductor device.

FIG. 16 is a diagram illustrating one example of a manufacturing step in the method for manufacturing the semiconductor device.

FIG. 17 is a diagram illustrating one example of a manufacturing step in the method for manufacturing the semiconductor device.

FIG. 18 is a diagram illustrating one example of a manufacturing step in the method for manufacturing the semiconductor device.

FIG. 19 is a diagram illustrating one example of a manufacturing step in the method for manufacturing the semiconductor device.

FIG. 20 is a diagram illustrating one example of a manufacturing step in the method for manufacturing the semiconductor device.

FIG. 21 is a diagram illustrating one example of a manufacturing step in the method for manufacturing the semiconductor device.

FIG. 22 is a cross-sectional view illustrating the cross-sectional structure of a cell region in a semiconductor device of a second embodiment.

FIG. 23 is a cross-sectional view illustrating one example of the cross-sectional structure of an FLR in a peripheral region.

FIG. 24 is a diagram illustrating one example of a manufacturing step in a method for manufacturing the semiconductor device of the second embodiment.

FIG. 25 is a diagram illustrating one example of a manufacturing step in the method for manufacturing the semiconductor device.

FIG. 26 is a diagram illustrating one example of a manufacturing step in the method for manufacturing the semiconductor device.

FIG. 27 is a diagram illustrating one example of a manufacturing step in the method for manufacturing the semiconductor device.

FIG. 28 is a diagram illustrating one example of a manufacturing step in the method for manufacturing the semiconductor device.

FIG. 29 is a diagram illustrating one example of a manufacturing step in the method for manufacturing the semiconductor device.

FIG. 30 is a diagram illustrating one example of a manufacturing step in the method for manufacturing the semiconductor device.

FIG. 31 is a diagram illustrating one example of a manufacturing step in the method for manufacturing the semiconductor device.

FIG. 32 is a diagram illustrating one example of a manufacturing step in the method for manufacturing the semiconductor device.

FIG. 33 is a diagram illustrating one example of a manufacturing step in the method for manufacturing the semiconductor device.

FIG. 34 is a diagram illustrating one example of a manufacturing step in the method for manufacturing the semiconductor device.

FIG. 35 is a diagram illustrating one example of a manufacturing step in the method for manufacturing the semiconductor device.

FIG. 36 is a diagram illustrating one example of a manufacturing step in the method for manufacturing the semiconductor device.

FIG. 37 is a diagram illustrating one example of a manufacturing step in the method for manufacturing the semiconductor device.

### DETAILED DESCRIPTION

Embodiments of a semiconductor device will now be described with reference to the drawings. The embodiments described below exemplify configurations and methods for embodying a technical concept without any intention to limit the material, shape, structure, arrangement, dimensions, and the like of each component.

### First Embodiment

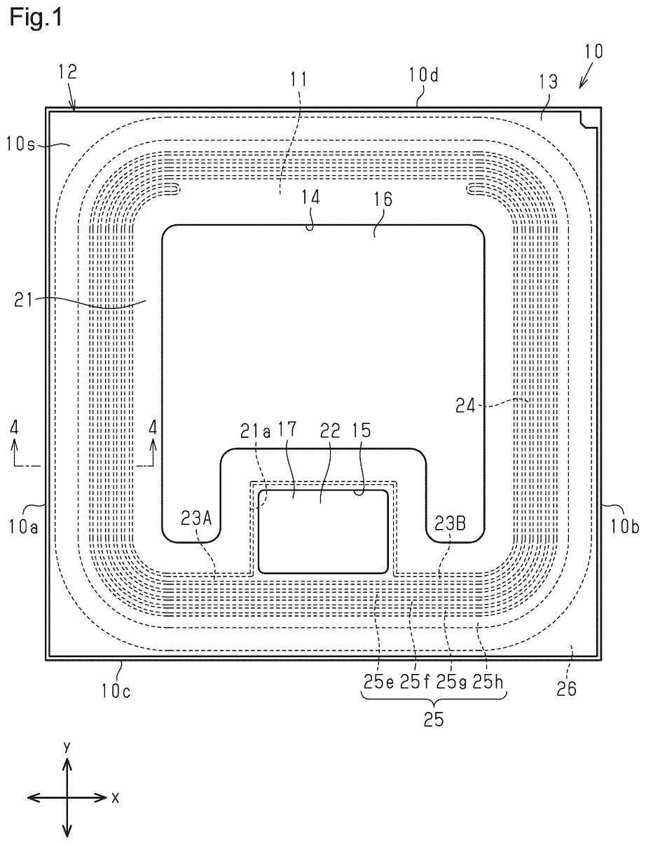

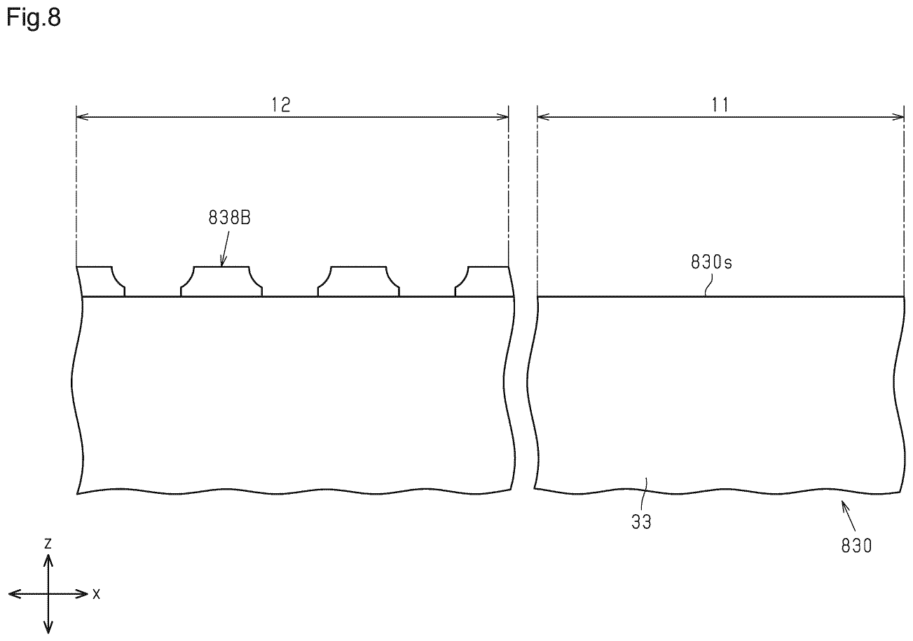

A semiconductor device 10 according to a first embodiment will now be described with reference to FIGS. 1 to 21. FIGS. 1 to 7 illustrate an example of the structure of the semiconductor device 10, and FIGS. 8 to 21 illustrate an example of a process for manufacturing the semiconductor device 10.

Structure of Semiconductor Device

The structure of the semiconductor device 10 according to the present embodiment will be described with reference to FIGS. 1 to 7.

As illustrated in FIG. 1, the semiconductor device 10 of the present embodiment is a trench gate type insulated-gate bipolar transistor (IGBT). The semiconductor device 10 is used as, for example a switching element in an on-vehicle inverter device. In this case, for example, a current of 5 A or greater and 1000 A or less flows through the semiconductor device 10.

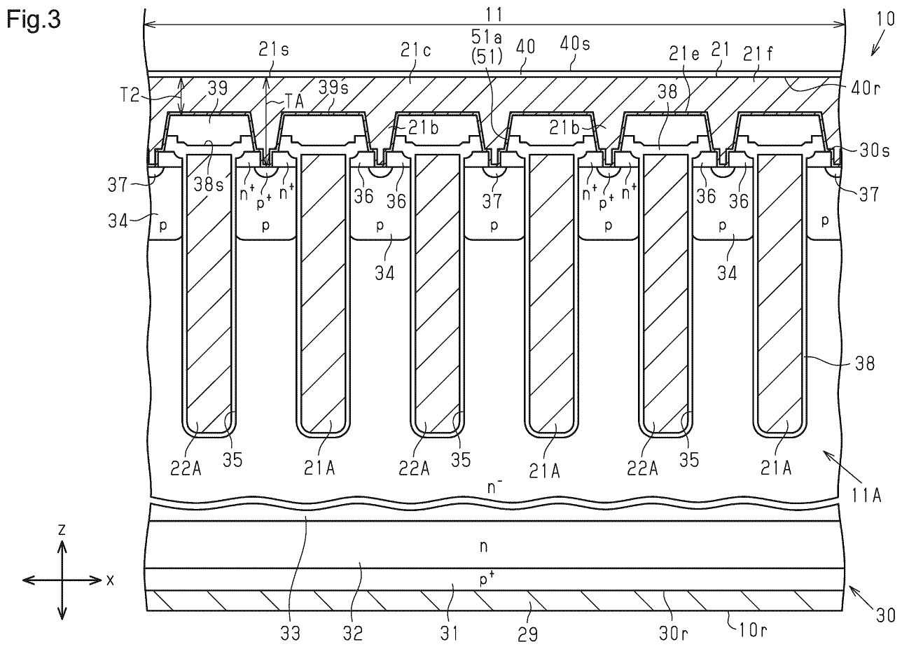

As illustrated in FIG. 1, the semiconductor device 10 has the form of a rectangular flat plate, for example. In the present embodiment, the semiconductor device 10 includes a device main surface 10s having a square shape, for example. In the present embodiment, the length of one side of the device main surface 10s is approximately 11 mm. That is, the chip size of the semiconductor device 10 of the present embodiment is 11 mm×11 mm. The semiconductor device 10 includes a device back surface 10r (refer to FIG. 3) opposite the device main surface 10s, and four device side surfaces 10a to 10d formed between the device main surface 10s and the device back surface 10r. The device side surfaces 10a to are, for example, surfaces connecting the device main surface 10s and the device back surface 10r, and are orthogonal to both the device main surface 10s and the device back surface 10r.

In the following description, the direction in which the device main surface 10s and the device back surface 10r face is referred to as the z-direction. The z-direction may also be referred to as the height direction of the semiconductor device 10. Two directions orthogonal to the z-direction and orthogonal to each other are referred to as the x-direction and the y-direction. In the present embodiment, the device side surfaces 10a, 10b form the two end surfaces of the semiconductor device 10 in the x-direction, and the device side surfaces 10c, 10d form the two end surfaces of the semiconductor device 10 in the y-direction. For the sake of simplicity, the direction extending from the device back surface 10r toward the device main surface 10s is referred to as the upward direction, and the direction extending from the device main surface 10s toward the device back surface 10r is referred to as the downward direction.

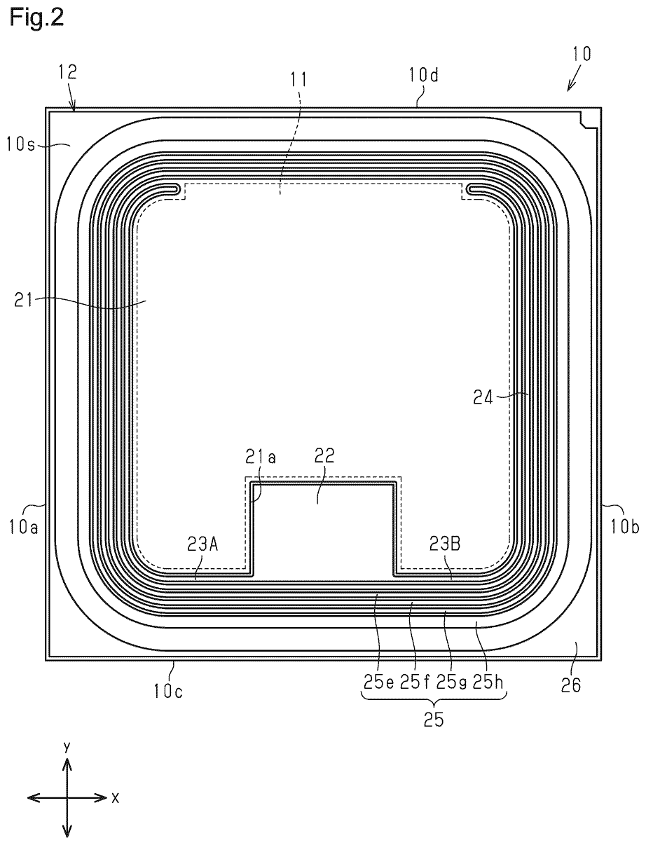

As illustrated in FIG. 2, the semiconductor device 10 includes an emitter electrode 21, a gate electrode 22, and a collector electrode 29 (refer to FIG. 3) as external electrodes for connecting to the semiconductor device 10 to an external device.

The emitter electrode 21 is an electrode forming an emitter of the IGBT through which the main current of the semiconductor device 10 flows. The emitter electrode 21 has an accommodation recess 21a recessed in the y-direction. The accommodation recess 21a is open toward the device side surface 10c. The emitter electrode 21 is formed on the device main surface 10s.

The gate electrode 22 forms the gate of the IGBT to which a drive voltage signal for driving the semiconductor device 10 is supplied from the outside the semiconductor device 10. The gate electrode 22 is provided at a position adjacent to the emitter electrode 21 in the y-direction. The gate electrode 22 is located in the accommodation recess 21a of the emitter electrode 21. The gate electrode 22 is formed on the device main surface 10s.

The collector electrode 29 forms the collector of the IGBT through which the main current of the semiconductor device 10 flows. Thus, in the semiconductor device 10, the main current flows from the collector electrode 29 toward the emitter electrode 21. The collector electrode 29 is formed on the device back surface 10r. More specifically, the collector electrode 29 is formed over the entire device back surface 10r.

As indicated by a broken line in FIG. 2, the semiconductor device 10 includes a cell region 11 in which a plurality of cells are formed, and a peripheral region 12 located at the outer side of the cell region 11 so as to surround the cell region 11. A cell refers to a main cell that forms a transistor. Thus, the cell region 11 includes a region where the transistor is formed. The peripheral region 12 is formed in the peripheral portion of the device main surface 10s as viewed in the z-direction.

The cell region 11 includes the emitter electrode 21. The emitter electrode 21 is formed over most of the cell region 11. As viewed in the z-direction, the emitter electrode 21 is shaped in conformance with the cell region 11. In the present embodiment, the emitter electrode 21 corresponds to an electrode portion.

The peripheral region 12 is a region provided with a terminal end structure that improves the dielectric strength of the semiconductor device 10. The peripheral region 12 is a region surrounding the emitter electrode 21 excluding where the gate electrode 22 is formed. The gate electrode 22 is provided in a region surrounded by the cell region 11 and the peripheral region 12.

The peripheral region 12 includes two gate fingers 23A and 23B, an emitter extension 24, a field limiting ring (FLR) 25, and an equipotential ring 26. The emitter electrode 21, the gate electrode 22, the gate fingers 23A and 23B, the emitter extension 24, the FLR 25, and the equipotential ring 26 share a common metal film. This metal film is formed from a material containing AlCu (an alloy of aluminum and copper), for example. In the present embodiment, the gate fingers 23A and 23B, the emitter extension 24, the FLR 25, and the equipotential ring 26 correspond to a peripheral electrode portion.

The two gate fingers 23A and 23B are configured to readily supply current from the gate electrode 22 to cells located at a portion of the emitter electrode 21 separated from the gate electrode 22. The two gate fingers 23A and 23B are integrated with the gate electrode 22. The two gate fingers 23A and 23B are connected to the one of the two ends of the gate electrode 22 in the y-direction that is closer to the device side surface 10c.

The gate finger 23A extends from the gate electrode 22 toward the device side surface 10a, and is formed to surround the emitter electrode 21 from the device side surface the device side surface 10a, and the device side surface 10d. The gate finger 23B extends from the gate electrode 22 toward the device side surface 10b, and is formed to surround the emitter electrode 21 from the device side surface 10c, the device side surface and the device side surface 10d. The distal end of the gate finger 23A and the distal end of the gate finger 23B face each other spaced apart by a gap in the x-direction at a portion located closer to the device side surface 10d than the emitter electrode 21.

The emitter extension 24 is a portion integrated with the emitter electrode 21, and has the form of a loop so as to surround the two gate fingers 23A and 23B.

The FLR 25 is a terminal end structure that increases the breakdown voltage of the semiconductor device 10, and is located outward from the emitter extension 24. The FLR has the form of a loop surrounding the emitter electrode 21 and the gate electrode 22. In the present embodiment, the FLR 25 has the form of a closed loop. The FLR 25 has the functionality for increasing the breakdown voltage of the semiconductor device 10 by weakening the electric field in the peripheral region 12 and limiting the effect of external ions.

The equipotential ring 26 is a terminal end structure that increases the breakdown voltage of the semiconductor device 10, and has the form of a loop so as to surround the FLR 25. As illustrated in FIG. 1, the equipotential ring 26 is formed at the outermost part of the device main surface 10s. In the present embodiment, the equipotential ring 26 has the form of a closed loop. The equipotential ring 26 has the functionality for increasing the breakdown voltage of the semiconductor device 10.

As illustrated in FIG. 1, the semiconductor device 10 includes a passivation film 13 that covers the emitter electrode 21, the gate electrode 22, the two gate fingers 23A and 23B, emitter extension 24, the FLR 25, and the equipotential ring 26. The passivation film 13 is a protective film that protects the semiconductor device 10 from the outside of the semiconductor device 10. The passivation film 13 is an organic insulation film formed from a material containing polyimide (PI), for example. The passivation film 13 covers the two gate fingers 23A and 23B, the emitter extension 24, the FLR 25, and the equipotential ring 26. Thus, the peripheral region 12 includes the passivation film 13.

The passivation film 13 has a first opening 14 and a second opening 15. The first opening 14 exposes part of the emitter electrode 21. This forms an emitter electrode pad 16. The second opening 15 exposes most of the gate electrode 22. This forms a gate electrode pad 17. As described above, the openings 14 and 15 form a pad for bonding of a conductive member (not illustrated) from the outer side of the semiconductor device 10.

FIG. 3 schematically illustrates an example of a cross-sectional structure of a part of the cell region 11. FIG. 3 shows some of the elements of the semiconductor device 10 in the cell region 11 without hatching lines for the sake of simplicity.

As illustrated in FIG. 3, the semiconductor device 10 includes a semiconductor substrate 30. The semiconductor substrate 30 is formed from a material containing an n⁻-type Si (silicon), for example. The semiconductor substrate 30 has a thickness 50 μm or greater and 200 μm or less, for example.

The semiconductor substrate 30 has a substrate head surface 30s and a substrate back surface 30r at opposite sides in the z-direction. Thus, the z-direction is the thickness direction of the semiconductor substrate 30.

The semiconductor substrate 30 has a structure in which a p⁺-type collector layer 31, an n-type buffer layer 32, and an n⁻-type drift layer 33 are stacked in this order from the substrate back surface 30r toward the substrate head surface 30s. The collector electrode 29 is formed on the substrate back surface 30r. The collector electrode 29 is formed over substantially the entire substrate back surface 30r. The surface of the collector electrode 29 on the opposite side of the substrate back surface 30r forms the device back surface 10r of the semiconductor device 10.

In the present embodiment, the z-direction is the thickness direction of the drift layer 33. Thus, a view in the z-direction is also a view in the thickness direction of the drift layer 33. The drift layer 33 corresponds to a first semiconductor layer. Thus, a view in the z-direction will also be a view in the first semiconductor layer.

The p-type dopant of the collector layer 31 is, for example, boron (B), aluminum (Al), or the like. The impurity concentration of the collector layer 31 is in, for example, a range of 1×10¹⁵ cm⁻³ to 2×10¹⁹ cm⁻³.

The n-type dopant of each of the buffer layer 32 and the drift layer 33 is, for example, nitrogen (N), phosphorus (P), arsenic (As), or the like. The impurity concentration of the buffer layer 32 is in, for example, a range of 1×10¹⁵ cm⁻³ to 5×10¹⁷ cm⁻³. The impurity concentration of the drift layer 33 is lower than that of the buffer layer 32, and in, for example, a range of 1×10¹³ cm⁻³ to 5×10¹⁴ cm⁻³.

A p-type base region 34 is formed on the head surface of the drift layer 33, that is, the substrate head surface 30s. The base region 34 is formed over substantially the entire head surface of the substrate head surface 30s. The impurity concentration of the base region 34 is higher than that of the drift layer 33, and is in, for example, a range of 1×10¹⁶ cm⁻³ to 1×10¹⁸ cm⁻³. The depth of the base region 34 from the substrate head surface is in, for example, a range of 1.0 μm to 4.0 μm.

Trenches 35 are arranged next to one another on the head surface of the base region 34 (substrate head surface 30s) in the cell region 11. The trenches 35, for example, extend in the y-direction and are separated from each other in the x-direction. This defines strips of main cells 11A. The interval between adjacent ones of the trenches 35 in the x-direction (distance between centers of trenches 35) is in, for example, a range of 1.5 μm to 7.0 μm. The width of each trench 35 (dimension of trench 35 in x-direction) is in, for example, a range of 0.5 μm to 3.0 μm. Each trench 35 extends through the base region 34 in the z-direction to the middle of the drift layer 33. The trenches 35 may be formed in a lattice pattern to define a matrix of the main cells 11A.

Further, n⁺-type emitter regions 36 are formed on the head surface of the base region 34 (substrate head surface 30s) in the cell region 11. The emitter regions 36 are located at opposite sides of each trench 35 in the x-direction. More specifically, in the arrangement direction of the trenches 35, the emitter regions 36 are located at opposite sides of each trench 35 in the base region 34. Thus, two emitter regions 36 are spaced apart from each other in the x-direction between adjacent ones of the trenches 35 in the x-direction. The depth of each emitter region 36 is in, for example, a range of 0.2 μm to 0.6 μm. The impurity concentration of each emitter region 36 is higher than that of the base region 34, and is in, for example, a range of 1×10¹⁹ cm⁻³ to 5×10²⁰ cm⁻³.

Additionally, p⁺-type base contact regions 37 is formed on the head surface of the base region 34 (substrate head surface 30s) in the cell region 11. The base contact regions 37 are located adjacent to the emitter regions 36 in the x-direction. More specifically, the base contact regions 37 are located between two adjacent ones of the emitter regions 36 in the x-direction that are located between adjacent ones of the trenches 35 in the x-direction. Each base contact region 37 may be deeper than the emitter region 36. Each base contact region 37 has a depth of, for example, 0.2 μm or more and 1.6 μm or less. The impurity concentration of each base contact region 37 is higher than that of the base region 34, and is in, for example, a range of 5×10¹⁸ cm⁻³ to 1×10²⁰ cm⁻³.

An insulation film 38 is formed integrally with the wall surface of each trench 35 and with the substrate head surface 30s. Thus, the insulation film 38 is formed on the head surface of the drift layer 33. The insulation film 38 includes, for example, silicon oxide (SiO₂). The thickness of the insulation film 38 is, for example, 1100 angstroms or greater and 1300 angstroms or less. The insulation film 38 in the cell region 11 may also be referred to as a gate insulation film.

An electrode material formed of, for example, polysilicon or the like is embedded in each trench 35 under the insulation film 38. The electrode material embedded in each trench 35 is electrically connected to the gate electrode 22 (gate fingers 23A and 23B) or the emitter electrode 21. That is, the electrode material embedded in the trenches 35 forms gate trenches 22A and emitter trenches 21A. In the present embodiment, the gate trenches 22A and the emitter trenches 21A are arranged alternately in the arrangement direction of the trenches 35. In the present embodiment, the gate trenches 22A and the emitter trenches 21A are embedded with the electrode material to the open ends of the trenches 35.

An intermediate insulation film 39 is formed on a head surface 38s of the insulation film 38, which is formed on the substrate head surface 30s. The intermediate insulation film 39 includes, for example, SiO₂. The thickness of the intermediate insulation film 39 is greater than the insulation film 38, and is, for example, 3000 angstroms or greater and 15000 angstroms or less.

The emitter electrode 21 is formed on the intermediate insulation film 39. That is, the intermediate insulation film 39 is an interlayer insulation film that fills the space between the emitter electrode 21 and each gate trench 22A and the space between the emitter electrode 21 and each emitter trench 21A.

Inner openings 51 extend through both the intermediate insulation film 39 and the insulation film 38 at positions overlapping the base contact regions 37 in the z-direction. The inner openings 51 expose the base contact regions 37 from the intermediate insulation film 39 and the insulation film 38. The inner openings 51 form contact holes allowing the emitter electrode 21 to contact the base contact region 37. There are multiple inner openings 51.

The emitter electrode 21 includes an electrode main body 21c formed on a head surface 39s of the intermediate insulation film 39, and embedded electrodes 21b embedded in the inner openings 51. In the present embodiment, the electrode main body 21c is integrated with each embedded electrode 21b. The electrode main body 21c is arranged on each embedded electrode 21b. The electrode main body 21c projects upward from the intermediate insulation film 39. In the present embodiment, the emitter electrode 21 corresponds to an electrode portion, and the electrode main body 21c corresponds to a stacked part.

More specifically, the emitter electrode 21 includes a barrier metal layer 21e. The barrier metal layer 21e is formed on the head surface 39s of the intermediate insulation film 39, a wall surface 51a of each inner opening 51, and the head surface of the drift layer 33 (substrate head surface 30s) exposed from the inner openings 51. The barrier metal layer 21e is formed by, for example, a stacked structure of titanium (Ti) and titanium nitride (TiN). Thus, the barrier metal layer 21e forms the portion of each embedded electrode 21b that contacts the wall surface 51a and the substrate head surface 30s and a portion of the electrode main body 21c that contacts the head surface 39s of the intermediate insulation film 39. An electrode layer 21f formed from a material containing AlCu is applied to the barrier metal layer 21e. That is, the emitter electrode 21 is formed by the stacked structure of the barrier metal layer 21e and the electrode layer 21f Thus, in the present embodiment, the embedded electrode 21b and the electrode main body 21c are formed integrally.

A barrier layer 40 is formed on the emitter electrode 21. The barrier layer 40 has functionality for limiting the entry of external ions from the passivation film 13 to the substrate head surface 30s of the semiconductor substrate 30. Specifically, the barrier layer 40 includes a material having a smaller diffusion coefficient of external ions than the passivation film 13. In the present embodiment, the barrier layer 40 includes a material having a smaller diffusion coefficient of external ions than the intermediate insulation film 39. The barrier layer 40 includes a material having a smaller diffusion coefficient of external ions than the insulation film 38. In summary, the barrier layer 40 includes a material having a smaller diffusion coefficient of external ions than each of the passivation film 13, the intermediate insulation film 39, and the insulation film 38. In other words, the passivation film 13 includes a material having a larger diffusion coefficient of external ions than the barrier layer 40. The barrier layer 40 is formed from a material containing silicon nitride, for example. In the present embodiment, the barrier layer 40 includes SiN as silicon nitride. The thickness of the barrier layer 40 is less than the thickness of the intermediate insulation film 39. Further, the thickness of the barrier layer 40 is less than the thickness of the passivation film 13. The barrier layer 40 is shaped in conformance with the head surface of the electrode main body 21c of the emitter electrode 21. The barrier layer 40 has a head surface 40s and a back surface 40r. The head surface 40s contacts the passivation film 13 (refer to FIG. 1), and the back surface 40r contacts the head surface of the electrode main body 21c of the emitter electrode 21. The barrier layer 40 is formed on a portion of the emitter electrode 21 covered with the passivation film 13, and is not formed on the emitter electrode pad 16 (refer to FIG. 1).

As viewed in the z-direction, the insulation film 38, the intermediate insulation film 39, and the barrier layer 40 are formed over substantially the entire head surface of the device main surface 10s. That is, the insulation film 38, the intermediate insulation film 39, and the barrier layer 40 are formed in both the cell region 11 and the peripheral region 12 as viewed in the z-direction. Although not illustrated, the barrier layer 40 is not formed on the gate electrode pad 17.

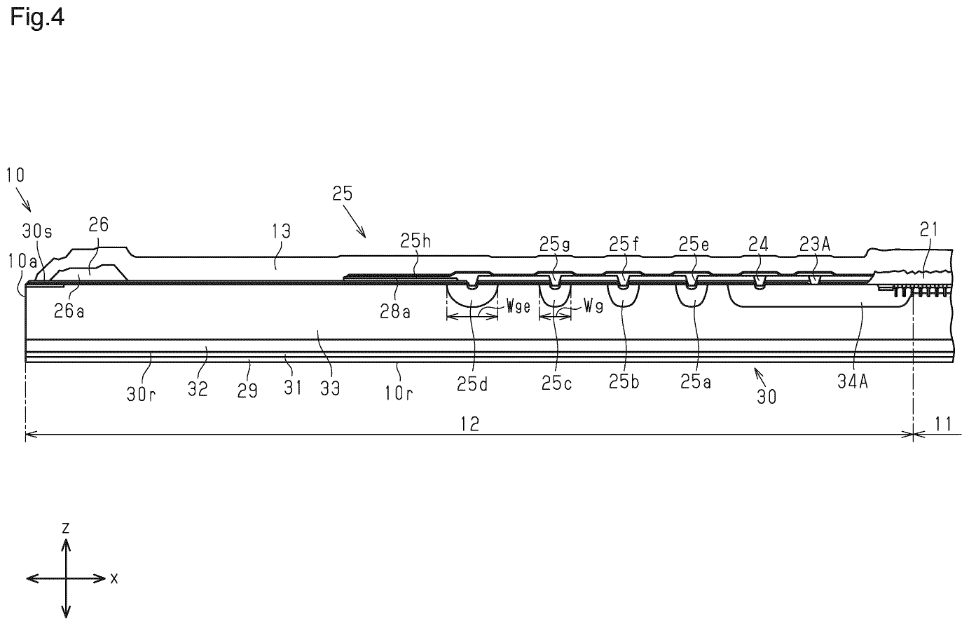

The peripheral region 12 will now be described in detail with reference to FIGS. 4 to 7.

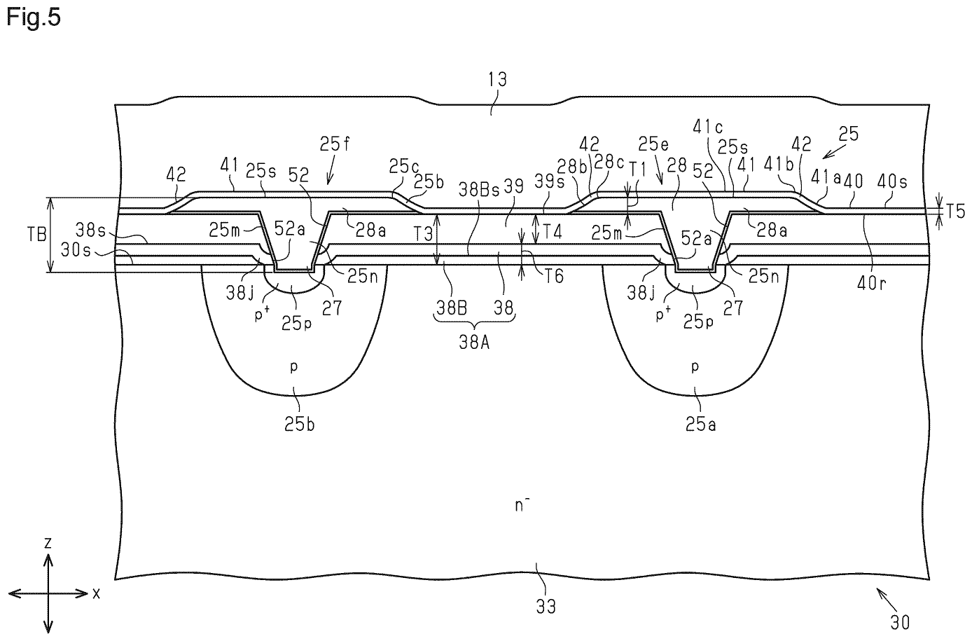

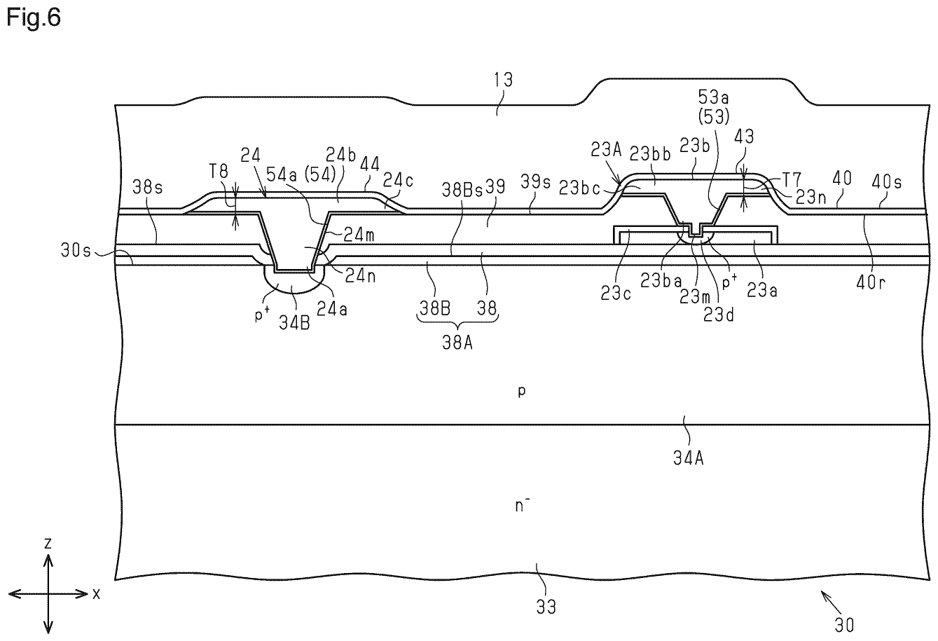

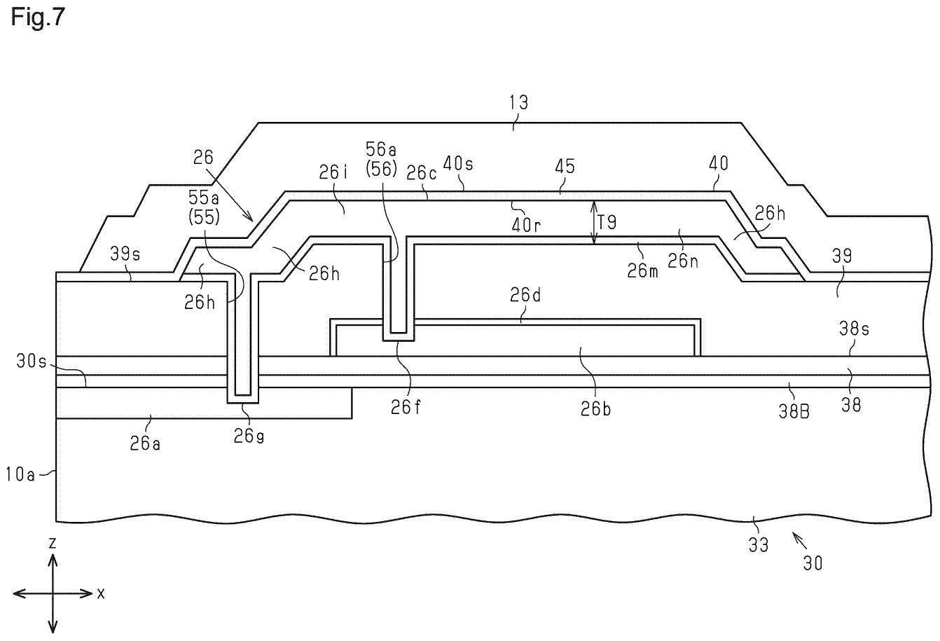

FIG. 4 illustrates the cross-sectional structure of part of the peripheral region 12. FIG. 5 is an enlarged view showing part of the FLR 25 and its surrounding in the peripheral region 12 of FIG. 4. FIG. 6 is an enlarged view of the gate finger 23A and the emitter extension 24 in the peripheral region 12 of FIG. 4. FIG. 7 is an enlarged view of part of the equipotential ring 26 and its surrounding in the peripheral region 12 of FIG. 4. FIGS. 4 to 7 show elements of the semiconductor device 10 without hatching lines for the sake of simplicity.

As illustrated in FIGS. 4 to 7, the drift layer 33 is also formed in the peripheral region 12. An insulation film 38A and the intermediate insulation film 39 are both formed on the substrate head surface 30s of the semiconductor substrate 30 in the peripheral region 12. Thus, the insulation film 38A and the intermediate insulation film 39 cover the head surface of the drift layer 33 in the peripheral region 12. The intermediate insulation film 39 is formed on the head surface of the insulation film 38A. The insulation film 38A in the peripheral region 12 includes the insulation film 38. The insulation film 38A is formed separately from the insulation film 38 in the cell region 11. Further, a barrier layer 40 is formed on the head surface 39s of the intermediate insulation film 39 in the peripheral region 12. In the present embodiment, the peripheral region 12 includes the insulation film 38A, the intermediate insulation film 39, and the barrier layer 40. In the present embodiment, the insulation film 38A and the intermediate insulation film 39 correspond to a peripheral insulation film. In the present embodiment, the insulation film 38A corresponds to a first insulation film, and the intermediate insulation film 39 corresponds to a second insulation film.

As illustrated in FIG. 6, the insulation film 38A includes a substrate-side insulation film 38B, which is formed on a substrate head surface 30s of the semiconductor substrate and the insulation film 38, which is formed on a head surface 38Bs of the substrate-side insulation film 38B and which serves as an insulation film located at the side opposite the substrate. That is, the insulation film 38A of the present embodiment is a double-layer stacked structure of the substrate-side insulation film 38B and the insulation film 38. The substrate-side insulation film 38B is an oxide film formed by thermally oxidizing the semiconductor substrate 30. Thus, the intermediate insulation film 39 stacked on the insulation film 38A is formed on the head surface 38s of the insulation film 38. The thickness of the substrate-side insulation film 38B is, for example, approximately 18000 angstroms.

As illustrated in FIG. 4, a p-type well region 34A is formed in a region adjacent to the cell region 11 in the peripheral region 12. In the same manner as the base region 34, the well region 34A is formed on the substrate head surface 30s of the semiconductor substrate 30. The well region 34A is partially formed in the drift layer 33. Thus, the head surface of the well region 34A is covered with the insulation film 38A and the intermediate insulation film 39. As described above, the insulation film 38A and the intermediate insulation film 39 (both shown in FIG. 5) cover the head surface of the drift layer 33 and the head surface of the well region 34A. In the present embodiment, the well region 34A is formed to surround the emitter electrode 21. The impurity concentration of the well region 34A is in, for example, a range of 1×10¹⁶ cm⁻³ to 1×10¹⁸ cm′.

The depth of the well region 34A in the peripheral region 12 is greater than the base region 34 (refer to FIG. 3) in the cell region 11. More specifically, the depth of the well region 34A in the peripheral region 12 is greater than that of the trench 35. In the present embodiment, the well region 34A extends to a position overlapping the periphery of the emitter electrode 21 as viewed in the z-direction. That is, the well region 34A is also formed in the periphery of the cell region 11. The barrier layer 40 (refer to FIG. 5) is provided at a position overlapping the well region 34A as viewed in the z-direction. The barrier layer 40 covers the well region 34A as viewed in the z-direction. In the present embodiment, the barrier layer 40 is formed to extend beyond the edge of the well region 34A as viewed in the z-direction. In the present embodiment, the well region 34A corresponds to a second semiconductor region of a second conductive type.

As illustrated in FIG. 4, the FLR 25 is formed at an outer side the well region 34A. The FLR 25 includes a plurality of (four in the present embodiment) looped conductors and semiconductor regions that are separated from one another.

A plurality of (four in the present embodiment) looped guard rings 25a to 25d are formed on the substrate head surface 30s of the semiconductor substrate 30. In the present embodiment, the guard rings 25a to 25d have the form of closed loops. The guard rings 25a to 25d are partially formed in the drift layer 33. The guard rings 25a to 25d are semiconductor regions of the second conductive type (p-type in the present embodiment), and are separated from one another in a direction orthogonal to the z-direction. The guard rings 25a to 25d are arranged in the order of the guard ring 25a, the guard ring 25b, the guard ring 25c, and the guard ring 25d from the emitter electrode 21. A width Wge of the outermost guard ring 25d is greater than widths Wg of the other guard rings 25a to 25c. The p-type dopant of each of the guard rings 25a to 25d is, for example, B, Al, or the like. The impurity concentration of each of the guard rings 25a to 25d is, for example, the same as the impurity concentration of the well region 34A, and is in, for example, a range of 1×10¹⁶ cm⁻³ to 1×10¹⁸ cm⁻³. In this case, the guard rings 25a to 25d and the well region 34A may be formed in the same process. In the present embodiment, the guard rings 25a to 25d correspond to the second semiconductor region of the second conductive type. The width Wge of the guard ring 25d can be changed freely. In one example, the width Wge of the guard ring 25d may be equal to the widths Wg of the guard rings 25a to 25c.

The FLR 25 includes field plates 25e to 25h arranged in correspondence with the guard rings 25a to 25d. As viewed in the z-direction, the field plate 25e is arranged overlapping the guard ring 25a, the field plate 25f is arranged overlapping the guard ring the field plate 25g is arranged overlapping the guard ring 25c, and the field plate 25h is arranged overlapping the guard ring 25d. The field plate 25e contacts the guard ring 25a, the field plate 25f contacts the guard ring 25b, the field plate 25g contacts the guard ring and the field plate 25h contacts the guard ring 25d. In the present embodiment, the field plates 25e to 25h correspond to a peripheral electrode portion.

FIG. 5 is an enlarged view of the guard rings 25a and 25b and the field plates 25e and 25f of the FLR 25 and their surroundings. The guard ring 25a and the field plate 25e have the same structure as the guard rings 25b, 25c and the field plates 25f, 25g. The guard ring 25d and the field plate 25h have the same structure as the guard ring 25a and the field plate 25e except in that the field plate 25h extends outward. Therefore, the structures of the guard ring 25a and the field plate 25e will be described below, and the structures of the guard rings 25b to 25d and the field plates 25f to 25h will not be described.

A peripheral opening 52 extends through both the intermediate insulation film 39 and the insulation film 38A at a position overlapping the guard ring 25a in a view of the barrier layer 40, the intermediate insulation film 39, and the insulation film 38A in the z-direction. As viewed in the z-direction, the open area of the peripheral opening 52 is smaller than the area of the head surface of the guard ring 25a. That is, the peripheral opening 52 forms a contact hole for exposing the part of the head surface of the guard ring 25a that will be in contact with the field plate 25e.

As illustrated in FIG. 5, the portion of the insulation film 38A forming the peripheral opening 52 is inclined toward the drift layer 33 as a wall surface 52a of the peripheral opening 52 becomes closer. In the present embodiment, the open end of the insulation film 38A includes a curved portion 38j. The curved portion 38j is curved so that the drift layer 33 becomes closer as the opening center of the peripheral opening 52 becomes closer. The intermediate insulation film 39 covers the curved portion 38j.

The field plate 25e extends into the peripheral opening 52 and contacts the guard ring 25a.

The field plate 25e includes an embedded electrode 27 in the peripheral opening 52 and a plate main body 28 having a projection 28a projecting sideward from the peripheral opening 52 on the intermediate insulation film 39. In the present embodiment, the projection 28a is formed on the head surface 39s of the intermediate insulation film 39.

More specifically, the field plate 25e includes a barrier metal layer 25m. The barrier metal layer 25m is formed on the head surface 39s of the intermediate insulation film 39, the wall surface 52a of the peripheral opening 52, and the head surface of the drift layer 33 (substrate head surface 30s) that is open at the peripheral opening 52. The barrier metal layer 25m is formed by, for example, a stacked structure of Ti and TiN. Thus, the barrier metal layer 25m forms a portion of the embedded electrode 27 contacting the wall surface 52a and the head surface of the drift layer 33, and a portion of the plate main body 28 contacting the head surface 39s of the intermediate insulation film 39. An electrode layer 25n formed from a material containing AlCu is provided on the barrier metal layer 25m. That is, the field plate 25e is formed by the stacked structure of the barrier metal layer 25m and the electrode layer 25n. Thus, in the present embodiment, the embedded electrode 27 and the plate main body 28 are formed integrally.

The plate main body 28 is arranged on the embedded electrode 27. The plate main body 28 projects from the intermediate insulation film 39 toward the direction opposite the drift layer 33. That is, the plate main body 28 projects upward from the intermediate insulation film 39. The projection 28a forms a portion of the plate main body 28 that extends outward from the peripheral opening 52. More specifically, as viewed in the z-direction, the projection 28a forms a portion extending outward from the peripheral opening 52 in a direction orthogonal to the direction in which the field plate 25e extends, that is, a portion extending outward from the peripheral opening 52 in the width direction of the field plate 25e. In the present embodiment, the projection 28a covers the entire guard ring 25a as viewed in the z-direction. The projection 28a has a portion extending beyond the edge of the guard ring 25a as viewed in the z-direction.

The plate main body 28 includes an inclined surface 28b that is curved and inclined toward the head surface 39s of the intermediate insulation film 39 as the outer end of the field plate 25e in the width direction becomes closer. In the present embodiment, the plate main body 28 is formed through wet etching. Thus, the plate main body 28 is processed and shaped during wet etching.

More specifically, the field plate 25e includes a head surface 25s, which is the part of the field plate 25e that is the farthest from the intermediate insulation film 39, and a curved surface 28c, which connects the head surface 25s and the inclined surface 28b. The head surface 25s is, for example, a surface facing the same direction as the head surface 39s of the intermediate insulation film 39, and overlaps the peripheral opening 52 as viewed in the z-direction. The curved surface 28c has an upwardly bulging curved surface smoothly connecting the head surface 25s and the inclined surface 28b.

As illustrated in FIGS. 3 and 5, a thickness TB of the field plate 25e is less than a thickness TA of the emitter electrode 21.

The thickness TB of the field plate 25e is the distance in the z-direction between the distal end surface of the embedded electrode 27 contacting a contact region 25p and the head surface 25s of the field plate 25e. That is, the thickness TB is the thickness of the thickest portion of the field plate 25e. In the present embodiment, the thickness TB of the field plate 25e is an average thickness when the thickness of the field plate 25e is measured at a number of locations in the field plate 25e.

The thickness TA (refer to FIG. 3) of the emitter electrode 21 is the distance in the z-direction between the distal end surface of the embedded electrode 21b contacting the base contact region 37 and a head surface 21s of the emitter electrode 21. That is, the thickness TA is the thickness of the thickest portion of the emitter electrode 21. In the present embodiment, the thickness TA of the emitter electrode 21 is an average thickness when the thickness of the emitter electrode 21 is measured at a number of locations in the emitter electrode 21.

The definition of the thickness TB of the field plate 25e is not limited to the average thickness, and may be changed as follows. The thickness TB of the field plate 25e may be the maximum thickness when the thickness of the field plate 25e is measured at a number of locations in the field plate 25e or may be the minimum thickness when the thickness of the field plate 25e is measured at a number of locations in the field plate 25e.

The definition of the thickness TA of the emitter electrode 21 may also be changed as follows. The thickness TA of the emitter electrode 21 may be the maximum thickness when the thickness of the emitter electrode 21 is measured at a number of locations in the emitter electrode 21 or may be the minimum thickness when the thickness of the emitter electrode 21 is measured at a number of locations in the emitter electrode 21.

A thickness T1 of the projection 28a of the field plate 25e is less than a thickness T2 of the electrode main body 21c of the emitter electrode 21. The thickness T1 of the projection 28a is, for example, 3 μm or less, and preferably 2 μm or less. More preferably, the thickness T1 of the projection 28a is approximately 1 μm.

The thickness T1 of the projection 28a is the distance in the z-direction between the head surface 39s of the intermediate insulation film 39 and the head surface 25s of the field plate 25e. That is, the thickness Ti is the thickness of the thickest portion of the projection 28a. In the present embodiment, the thickness T1 of the projection 28a is an average thickness when the thickness of the projection 28a is measured at a number of locations in the field plate 25e.

The thickness T2 of the electrode main body 21c is the distance in the z-direction between the head surface 39s of the intermediate insulation film 39 and the head surface 21s of the emitter electrode 21. The head surface 21s is a surface of the emitter electrode 21 facing the same direction as the head surface 39s of the intermediate insulation film 39. In the present embodiment, the thickness T2 of the electrode main body 21c is an average thickness when the thickness of the electrode main body 21c is measured at a number of locations in the emitter electrode 21.

The definition of the thickness T1 of the projection 28a is not limited to the average thickness, and may be changed as follows. The thickness T1 of the projection 28a may be the maximum thickness when the thickness of the projection 28a is measured at a number of locations in the field plate 25e or may be the minimum thickness when the thickness of the projection 28a is measured at a number of locations in the field plate 25e.

The definition of the thickness T2 of the electrode main body 21c may also be changed as follows. The thickness T2 of the electrode main body 21c may be the maximum thickness when the thickness of the electrode main body 21c is measured at a number of locations in the emitter electrode 21 or may be the minimum thickness when the thickness of the electrode main body 21c is measured at a number of locations in the emitter electrode 21.

Even if the thickness T1 of the projection 28a is defined as the maximum thickness when the thickness of the projection 28a is measured at a number of locations in the field plate 25e and the thickness T2 of the electrode main body 21c is defined as the minimum thickness when the thickness of the electrode main body 21c is measured at a number of locations in the emitter electrode 21, the thickness T1 of the projection 28a is preferably less than the thickness T2 of the electrode main body 21c.

As illustrated in FIG. 5, the thickness T1 of the projection 28a is less than a thickness T3 of the stacked structure of the intermediate insulation film 39 and the insulation film 38A. The thickness T1 of the projection 28a is greater than a thickness T4 of the intermediate insulation film 39. The thickness T1 of the projection 28a may be equal to the thickness T4 of the intermediate insulation film 39.

The thickness T3 of the stacked structure of the intermediate insulation film 39 and the insulation film 38A is the distance in the z-direction between the substrate head surface 30s of the semiconductor substrate 30 and the head surface 39s of the intermediate insulation film 39. In the present embodiment, the thickness T3 of the stacked structure of the intermediate insulation film 39 and the insulation film 38A is an average thickness when the thickness of the stacked structure of the intermediate insulation film 39 and the insulation film 38A is measured at a number of locations.

The thickness T4 of the intermediate insulation film 39 is the distance in the z-direction between the head surface 38s of the insulation film 38 and the head surface 39s of the intermediate insulation film 39. In the present embodiment, the thickness T4 of the intermediate insulation film 39 is an average thickness when the thickness of the intermediate insulation film 39 is measured at a number of locations.

The thickness T3 of the stacked structure of the intermediate insulation film 39 and the insulation film 38A is not limited to the above average thickness, and may be changed as follows. The thickness T3 of the stacked structure of the intermediate insulation film 39 and the insulation film 38A may be the maximum thickness when the thickness of the stacked structure of the intermediate insulation film 39 and the insulation film 38A is measured at a number of locations in the peripheral region 12 or the thickness T3 of the stacked structure of the intermediate insulation film 39 and the insulation film 38A may be the minimum thickness when the thickness of the stacked structure of the intermediate insulation film 39 and the insulation film 38A is measured at a number of locations in the peripheral region 12.

In the same manner as the thickness T3, the thickness T4 of the intermediate insulation film 39 may also be changed as follows. The thickness T4 of the intermediate insulation film 39 may be the maximum thickness when the thickness of the intermediate insulation film 39 is measured at a number of locations in the peripheral region 12 or may be the minimum thickness when the thickness of the intermediate insulation film 39 is measured at a number of locations in the peripheral region 12.

Even if the thickness T1 of the projection 28a is defined as the maximum thickness when the thickness of the projection 28a is measured at a number of locations in the field plate 25e and the thickness T3 of the stacked structure of the intermediate insulation film 39 and the insulation film 38A is defined as the minimum thickness when the thickness of the stacked structure of the intermediate insulation film 39 and the insulation film 38A is measured at a number of locations in the peripheral region 12, the thickness T1 of the projection 28a is preferably less than the thickness T3 of the stacked structure of the intermediate insulation film 39 and the insulation film 38A.

In the present embodiment, the thickness T1 of the projection 28a is greater than a thickness T5 of the barrier layer 40. In other words, the thickness T5 of the barrier layer 40 is less than the thickness T1 of the projection 28a. The thickness T1 of the projection 28a is greater than a thickness T6 of the insulation film 38A. The thickness T1 of the projection 28a may be less than or equal to the thickness T6 of the insulation film 38A.

The thickness T5 of the barrier layer 40 is the distance in the z-direction between the head surface 39s of the intermediate insulation film 39 and the head surface 40s of the barrier layer 40. In the present embodiment, the thickness T5 of the barrier layer 40 is an average thickness when the thickness of the barrier layer 40 is measured at a number of locations.

The thickness T6 of the insulation film 38 is the distance in the z-direction between the substrate head surface 30s of the semiconductor substrate 30 and the head surface 38s of the insulation film 38. In the present embodiment, the thickness T6 of the insulation film 38A is an average thickness when the thickness of the insulation film 38A is measured at a number of locations.

The thickness T5 of the barrier layer 40 is not limited to the average thickness, and may be changed as follows. The thickness T5 of the barrier layer 40 may be the maximum thickness when the thickness of the barrier layer 40 is measured at a number of locations in the peripheral region 12 or may be the minimum thickness when the thickness of the barrier layer 40 is measured at a number of locations in the peripheral region 12.

Further, the thickness T6 of the insulation film 38A may also be changed as follows, in the same manner as the thickness T5. The thickness T6 of the insulation film 38 may be the maximum thickness when the thickness of the insulation film 38A is measured at a number of locations in the peripheral region 12 or may be the minimum thickness when the thickness of the insulation film 38A is measured at a number of locations in the peripheral region 12.

The lower end of the embedded electrode 27 is embedded in the upper portion of the guard ring 25a. A p⁺-type contact region 25p is formed in a portion of the guard ring 25a corresponding to the embedded electrode 27. The p-type dopant of the contact region 25p is, for example, B, Al, or the like. The impurity concentration of the contact region 25p is higher than that of the guard ring 25a, and is in, for example, a range of 5×10¹⁸ cm⁻³ to 1×10²⁰ cm⁻³.

The barrier layer 40 is stepped to cover both the intermediate insulation film 39 and the field plate 25e. The barrier layer 40 includes a plate cover portion 41 that covers the plate main body 28. Steps 42 are formed at where by the plate cover portion 41 covers the two ends of the field plate 25e in the width direction. The width direction of the field plate 25e is a direction orthogonal to the direction in which the field plate 25e extends as viewed in the z-direction. The projection 28a extends beyond the edge of the guard ring 25a as viewed in the z-direction. Thus, the step 42 is located outward from the edge of the guard ring 25a. When the distal end of the step 42 in the width direction of the field plate 25e is located outward from the edge of the guard ring 25a, the step 42 is located outward from the edge of the guard ring 25a. In the present embodiment, the entire step 42 is located outward from the edge of the guard ring 25a as viewed in the z-direction.

The plate cover portion 41 of the barrier layer 40 is shaped in conformance with the head surface of the plate main body 28. That is, the plate cover portion 41 includes an inclined surface 41a that covers the inclined surface 28b of the plate main body 28, a curved portion 41b that covers the curved surface 28c of the plate main body 28, and a head surface portion 41c that covers the head surface of the plate main body 28 (e.g., the head surface 25s of the field plate 25e). Thus, the plate cover portion 41 of the barrier layer 40 is smoothly curved along the head surface of the plate main body 28. The passivation film 13 is stacked on the barrier layer 40.

As illustrated in FIG. 4, the length of the projection 28a of the field plate 25h, extending at the side opposite the field plate 25g is greater than the length of the projection 28a of the field plate 25e. A portion of the projection 28a of the field plate 25h extending at the opposite side of the field plate 25g extends beyond the guard ring 25d as viewed in the z-direction.

As illustrated in FIG. 4, the gate finger 23A (23B) and the emitter extension 24 overlap the well region 34A as viewed in the z-direction. The gate finger 23A (23B) is spaced apart from the emitter electrode 21 in the outward direction.

As illustrated in FIG. 6, the gate finger 23A includes a gate layer 23a formed on the head surface 38s of the insulation film 38, and a gate interconnection 23b formed on the head surface 40s of the barrier layer 40.

The gate layer 23a is formed from polysilicon, for example, surrounding the emitter electrode 21 from the device side surface 10c, the device side surface 10a, and the device side surface 10d (refer to FIG. 1). The gate layer 23a is covered by the intermediate insulation film 39. An oxide film 23c is formed on the gate layer 23a.

The gate interconnection 23b is provided at a position overlapping the gate layer 23a as viewed in the z-direction. The gate interconnection 23b is integrated with the gate electrode 22.

A peripheral opening 53 extends through both the intermediate insulation film 39 and the oxide film 23c at a position corresponding to the gate finger 23A in the intermediate insulation film 39 and the oxide film 23c. Thus, the gate layer 23a is exposed through the peripheral opening 53. The gate interconnection 23b enters the peripheral opening 53 and contacts the gate layer 23a. That is, the peripheral opening 53 forms a contact hole to allow the gate interconnection 23b to contact the gate layer 23a.

The gate interconnection 23b includes an embedded electrode 23ba, which is provided in the peripheral opening 53, and an interconnection main body 23bb, which has a projection 23bc that projects sideward from the embedded electrode 23ba and covers the intermediate insulation film 39.

More specifically, the gate interconnection 23b includes a barrier metal layer 23m. The barrier metal layer 23m is formed on the head surface 39s of the intermediate insulation film 39, a wall surface 53a forming the peripheral opening 53, and the head surface of the drift layer 33 (substrate head surface 30s) exposed from the peripheral opening 53. The barrier metal layer 23m is formed by, for example, a stacked structure of Ti and TiN. Thus, the barrier metal layer 23m forms a portion of the embedded electrode 23ba contacting the wall surface 53a, the head surface of the drift layer 33, and a portion of the interconnection main body 23bb contacting the head surface 39s of the intermediate insulation film 39. An electrode layer 23n formed from a material containing AlCu is provided on the barrier metal layer 23m. That is, the gate interconnection 23b is formed by the stacked structure of the barrier metal layer 23m and the electrode layer 23n. Thus, in the present embodiment, the embedded electrode 23ba and the interconnection main body 23bb is formed integrally.

A thickness T7 of the projection 23bc is equal to the thickness T1 (refer to FIG. 5) of the projection 28a of the field plate 25e. When the difference between the thickness T7 and the thickness T1 is, for example, within 20% of the thickness T7, the thickness T7 and the thickness T1 are equal.

A contact region 23d, which is a pt semiconductor region, is formed in a portion where the embedded electrode 23ba is embedded in the gate layer 23a. The p-type dopant of the contact region 23d is, for example, B, Al, or the like. The impurity concentration of the contact region 23d is higher than that of the well region 34A, and is in, for example, a range of 5×10¹⁸ cm⁻³ to 1×10²⁰ cm⁻³.

The interconnection main body 23bb is arranged on the embedded electrode 23ba. The interconnection main body 23bb projects from the intermediate insulation film 39 at the side opposite the well region 34A. That is, the interconnection main body 23bb projects upward from the intermediate insulation film 39. The projection 23bc forms a portion of the interconnection main body 23bb extending outside the peripheral opening 53. More specifically, as viewed in the z-direction, the projection 23bc forms a portion extending outside the peripheral opening 53 in a direction orthogonal to the direction in which the gate interconnection 23b extends. That is, the projection forms a portion extending outside the peripheral opening 53 of the gate interconnection 23b in the width direction. The interconnection main body 23bb is inclined and curved toward the head surface 39s of the intermediate insulation film 39 as the outer side of the gate interconnection 23b in the width direction becomes closer. The interconnection main body 23bb is formed through wet etching. The interconnection main body 23bb is shaped through wet etching. In the present embodiment, the interconnection main body 23bb has the same shape as the plate main body 28 of the field plate 25e.

The barrier layer 40 is stepped to cover both the intermediate insulation film 39 and the gate finger 23A. In the barrier layer 40, an interconnection cover portion 43 covering the interconnection main body 23bb is shaped in conformance with the head surface shape of the interconnection main body 23bb. The interconnection cover portion 43 of the barrier layer 40 is shaped to be smoothly curved along the head surface of the interconnection main body 23bb. The passivation film 13 is stacked on the barrier layer 40.

The emitter extension 24 is formed from a metal film on the head surface 40s of the barrier layer 40. The emitter extension 24 is formed in the periphery of the well region 34A.

A peripheral opening 54 extends through all of the intermediate insulation film 39 and the insulation film 38 at a position corresponding to the emitter extension 24 in the intermediate insulation film 39 and the insulation film 38. Thus, the well region 34A is exposed through the peripheral opening 54. The emitter extension 24 enters the peripheral opening 54 and contacts the well region 34A. That is, the peripheral opening 54 forms a contact hole allowing the emitter extension 24 to contact the well region 34A.

The emitter extension 24 includes an embedded electrode 24a, which is embedded in the peripheral opening 54, and an interconnection main body 24b, which has a projection 24c projecting sideward from the embedded electrode 24a and which covers the intermediate insulation film 39.

More specifically, the emitter extension 24 includes a barrier metal layer 24m. The barrier metal layer 24m is formed on the head surface 39s of the intermediate insulation film 39, a wall surface 54a forming the peripheral opening 54, and the head surface of the drift layer 33 (substrate head surface 30s) exposed from the peripheral opening 54. The barrier metal layer 24m is formed by, for example, a stacked structure of Ti and TiN. Thus, the barrier metal layer 24m forms a portion of the embedded electrode 24a that is in contact with the wall surface 54a, the head surface of the drift layer 33, and the portion of the interconnection main body 24b contacting the head surface 39s of the intermediate insulation film 39. An electrode layer 24n formed from a material containing AlCu is formed on the barrier metal layer 24m. That is, the emitter extension 24 is formed by the stacked structure of the barrier metal layer 24m and the electrode layer 24n. Thus, in the present embodiment, the embedded electrode 24a and the interconnection main body 24b are formed integrally.

The projection 24c is located in the well region 34A as viewed in the z-direction. A thickness T8 of the projection 24c is equal to the thickness T1 (refer to FIG. 5) of the projection 28a of the field plate 25e. When the difference between the thickness T8 and the thickness T1 is, for example, within 20% of the thickness T8, the thickness T8 is equal to the thickness Ti.

The lower end of the embedded electrode 24a is embedded in the upper portion of the well region 34A. A p⁺-type contact region 34B is formed in a portion of the well region 34A corresponding to the embedded electrode 24a. The p-type dopant of the contact region 34B is, for example, B, Al, or the like. The impurity concentration of the contact region 34B is higher than that of the well region 34A, and is in, for example, a range of 5×10¹⁸ cm⁻³ to 1×10²⁰ cm⁻³.

The interconnection main body 24b is arranged on the embedded electrode 24a. The interconnection main body 24b projects from the side of the intermediate insulation film 39 opposite the well region 34A. That is, the interconnection main body 24b projects upward from the intermediate insulation film 39. The projection 24c forms the portion of the interconnection main body 24b extending outside the peripheral opening 54. More specifically, as viewed in the z-direction, the projection 24c forms a portion extending outside the peripheral opening 54 in a direction orthogonal to the direction in which the emitter extension 24 extends, that is, a portion extending outside the peripheral opening 54 of the emitter extension 24 in the width direction. The interconnection main body 24b is inclined and curved shape toward the head surface 39s of the intermediate insulation film 39 as the outer side of the emitter extension 24 in the width direction becomes closer. The interconnection main body 24b is formed through wet etching. The interconnection main body 24b is shaped through wet etching. In the present embodiment, the interconnection main body 24b has the same the shape as the plate main body 28 of the field plate 25e.

The barrier layer 40 is stepped to cover both the intermediate insulation film 39 and the emitter extension 24. In the barrier layer 40, the interconnection cover portion 44 covering the interconnection main body 24b is shaped in conformance with the head surface of the interconnection main body 24b. The interconnection cover portion 44 of the barrier layer 40 is shaped to be smoothly curved along the head surface of the interconnection main body 24b. The passivation film 13 is stacked on the barrier layer 40.

As illustrated in FIG. 4, the equipotential ring 26 is formed at the outer side of the FLR 25.

As illustrated in FIG. 7, the equipotential ring 26 includes a channel stop region 26a of the first conductive type (n⁺-type) formed on the head surface of the drift layer 33 (substrate head surface 30s), an internal interconnection 26b arranged in the insulation film 38 and the intermediate insulation film 39, and a head surface interconnection 26c on the head surface 39s of the intermediate insulation film 39.

The channel stop region 26a is formed from a position overlapping the head surface interconnection 26c to the device side surface 10a as viewed in the z-direction. The channel stop region 26a is located outside the internal interconnection 26b (near the device side surface 10a). The impurity concentration of the channel stop region 26a is, for example, the same as the impurity concentration of the emitter region 36 (refer to FIG. 3), and is in a range of 1×10¹⁹ cm⁻³ to 5×10²⁰ cm⁻³. In this case, for example, the channel stop region 26a is formed in the same process as the emitter region 36.

The internal interconnection 26b is arranged on the head surface 38s of the insulation film 38 and covered by the intermediate insulation film 39. The internal interconnection 26b is formed of an electrode material such as polysilicon. The internal interconnection 26b is formed in the same process as the gate layer 23a (refer to FIG. 5) of the gate finger 23A. An oxide film 26d is formed on the head surface of the internal interconnection 26b.

A peripheral opening 55 is provided at a position corresponding to the channel stop region 26a in the barrier layer 40, the intermediate insulation film 39, and the oxide film 23c. The peripheral opening 55 extends through the intermediate insulation film 39, the insulation film 38, and the substrate-side insulation film 38B in the z-direction. Thus, the channel stop region 26a is exposed through the peripheral opening 55. The head surface interconnection 26c enters the peripheral opening 55 and contacts the channel stop region 26a. That is, the peripheral opening 55 forms a contact hole allowing the head surface interconnection 26c to contact the channel stop region 26a.

A peripheral opening 56 is arranged at a position corresponding to the internal interconnection 26b in the barrier layer 40, the intermediate insulation film 39, and the oxide film 26d. In the peripheral opening 56, the internal interconnection 26b extends through both the intermediate insulation film 39 and the oxide film 26d in the z-direction. Thus, the internal interconnection 26b is exposed through the peripheral opening 56. The head surface interconnection 26c enters the peripheral opening 56 and contacts the internal interconnection 26b. That is, the peripheral opening 56 forms a contact hole that allows the head surface interconnection 26c to contact the internal interconnection 26b.

The head surface interconnection 26c includes two embedded electrodes 26f and 26g and an interconnection main body 26i, which has a projection 26h that projects sideward from the embedded electrodes 26f and 26g and overlaps the intermediate insulation film 39.

More specifically, the head surface interconnection 26c includes a barrier metal layer 26m. The barrier metal layer 26m is formed on the head surface 39s of the intermediate insulation film 39, a wall surface 55a of the peripheral opening 55, the head surface of the drift layer 33 (substrate head surface 30s) that opens in the peripheral opening 55, a wall surface 56a of the peripheral opening 56, and the head surface of the internal interconnection 26b that opens in the peripheral opening 56. Thus, the barrier metal layer 26m forms a portion of the embedded electrode 26f contacting the wall surface 55a and a portion contacting the head surface of the channel stop region 26a. The barrier metal layer 26m forms a portion of the embedded electrode 26g contacting the wall surface 56a and a portion contacting the head surface of the internal interconnection 26b. The barrier metal layer 26m forms a portion of the interconnection main body 26i contacting the head surface 39s of the intermediate insulation film 39. The barrier metal layer 26m is formed by, for example, a stacked structure of Ti and TiN. An electrode layer 26n formed from a material containing AlCu is formed on the barrier metal layer 26m. That is, the head surface interconnection 26c is formed by the stacked structure of the barrier metal layer 26m and the electrode layer 26n. Thus, in the present embodiment, the embedded electrodes 26f and 26g are formed integrally with the interconnection main body 26i.

The embedded electrode 26f is located at a position overlapping both the channel stop region 26a and the interconnection main body 26i as viewed in the z-direction. The embedded electrode 26f extends through all of the insulation films 38 and 38B on the channel stop region 26a and the intermediate insulation film 39 on the insulation film 38 in the z-direction.

The embedded electrode 26g overlaps both the internal interconnection 26b and the interconnection main body 26i as viewed in the z-direction. The embedded electrode 26g is arranged inside the embedded electrode 26f. The embedded electrode 26g extends through both the oxide film 26d on the internal interconnection 26b and the intermediate insulation film 39 in the z-direction. In the present embodiment, the embedded electrode 26g is embedded in the upper portion of the internal interconnection 26b.

The interconnection main body 26i is arranged on the embedded electrodes 26f and 26g. The interconnection main body 26i projects from the intermediate insulation film 39 in a direction opposite the drift layer 33. That is, the interconnection main body 26i projects upward from the intermediate insulation film 39. The projection 26h forms the end of the interconnection main body 26i and the portion of the interconnection main body 26i between the embedded electrode 26f and the embedded electrode 26g as viewed in the z-direction. More specifically, as viewed in the z-direction, the projection 26h forms the two ends in a direction orthogonal to the direction in which the head surface interconnection 26c extends, or the two ends of the head surface interconnection 26c in the width direction, and a portion between the embedded electrode 26f and the embedded electrode 26g in a direction in which the head surface interconnection 26c extends.

A thickness T9 of the projection 26h is equal to the thickness Ti (refer to FIG. 5) of the projection 28a of the field plate 25e. When the difference between the thickness T9 and the thickness Ti is, for example, within 20% of the thickness T8, the thickness T9 and the thickness Ti are equal.

The barrier layer 40 is stepped to cover both the intermediate insulation film 39 and the head surface interconnection 26c. In the barrier layer 40, the interconnection cover portion 45 covering the interconnection main body 26i is shaped in conformance with the head surface of the interconnection main body 26i. The interconnection cover portion 45 of the barrier layer 40 is shaped to be smoothly curved along the head surface shape of the interconnection main body 26i. The passivation film 13 is stacked on the barrier layer 40.

As illustrated in FIGS. 4 to 7, the peripheral region 12 is covered by a passivation film 13. That is, the barrier layer 40 is covered by the passivation film 13 as viewed in the z-direction. Thus, the barrier layer 40 is located between the passivation film 13 and the drift layer 33. The passivation film 13 is located upward from the intermediate insulation film 39 overlapping the intermediate insulation film 39 as viewed in the z-direction. That is, the passivation film 13 covers the intermediate insulation film 39.

Method for Manufacturing Semiconductor Device

A method for manufacturing the semiconductor device 10 according to the present embodiment will now be described with reference to FIGS. 8 to 21. The semiconductor device 10 is shown in a simplified manner in FIGS. 8 to 21 for the sake of convenience. Therefore, the elements of the semiconductor device 10 shown in FIGS. 8 to 21 may differ in shape and size from the elements of the semiconductor device 10 shown in FIGS. 1 to 7. FIGS. 8 to 21 illustrate manufacturing steps for part of the cell region 11 and part of the FLR 25. A method for manufacturing a single semiconductor device 10 will be described with reference to FIGS. 8 to 21. The method for manufacturing the semiconductor device 10 of the present embodiment is not limited to manufacturing a single semiconductor device 10. Thus, the method may be employed to manufacturing multiple semiconductor devices 10.

The method for manufacturing the semiconductor device 10 according to the present embodiment includes a step of preparing a semiconductor substrate 830 formed from a material containing Si. The semiconductor substrate 830 includes an n⁻-type drift layer 33 as a semiconductor layer of a first conductive type. The drift layer 33 is formed over the entire semiconductor substrate 830. The semiconductor substrate 830 has a substrate head surface 830s and a substrate back surface (not illustrated) at opposite sides in the thickness direction (z-direction). Thus, the substrate head surface 830s is the head surface of the drift layer 33. The drift layer 33 is formed over the entire semiconductor substrate 830. Hence the drift layer 33 is formed in both the cell region 11 and the peripheral region 12. In the present embodiment, the step of preparing the semiconductor substrate 830 corresponds to forming a first semiconductor layer of a first conductive type in the peripheral region.

As illustrated in FIG. 8, the method for manufacturing the semiconductor device 10 of the present embodiment includes a step of forming a substrate-side insulation film 838B in a portion corresponding to the peripheral region 12 in the substrate head surface 830s of the semiconductor substrate 830. The substrate-side insulation film 838B is an insulation film corresponding to the substrate-side insulation film 38B of the semiconductor device 10.

The step of forming the substrate-side insulation film 838B includes a step of thermally oxidizing the semiconductor substrate 830 to form a first insulation layer on the substrate head surface 830s, a step of wet etching the first insulation layer, and a step of dry etching the first insulation layer.

Specifically, the semiconductor substrate 830 is first thermally oxidized to form an oxide film on the entire head surface of the semiconductor substrate 830. In this case, the oxide film is a silicon oxide film (SiO₂). Subsequently, a portion of the oxide film on the substrate head surface 830s of the semiconductor substrate 830, excluding the peripheral region 12, is removed. More specifically, the oxide film is first wet etched and reduced in thickness. A mask is used to partially reduce the thickness of the oxide film in the peripheral region 12. Subsequently, the oxide film is dry etched and removed. In the peripheral region 12, a portion exposed from a mask is removed through dry etching. Through the above steps, the substrate-side insulation film 838B is formed on the substrate head surface 830s of the semiconductor substrate 830. In the present embodiment, the step of forming the substrate-side insulation film 838B includes a step of forming the first insulation layer (oxide film) by thermally oxidizing both the head surface of the first semiconductor layer and the head surface of the second semiconductor region, and a step of wet etching and then dry etching the first insulation layer.

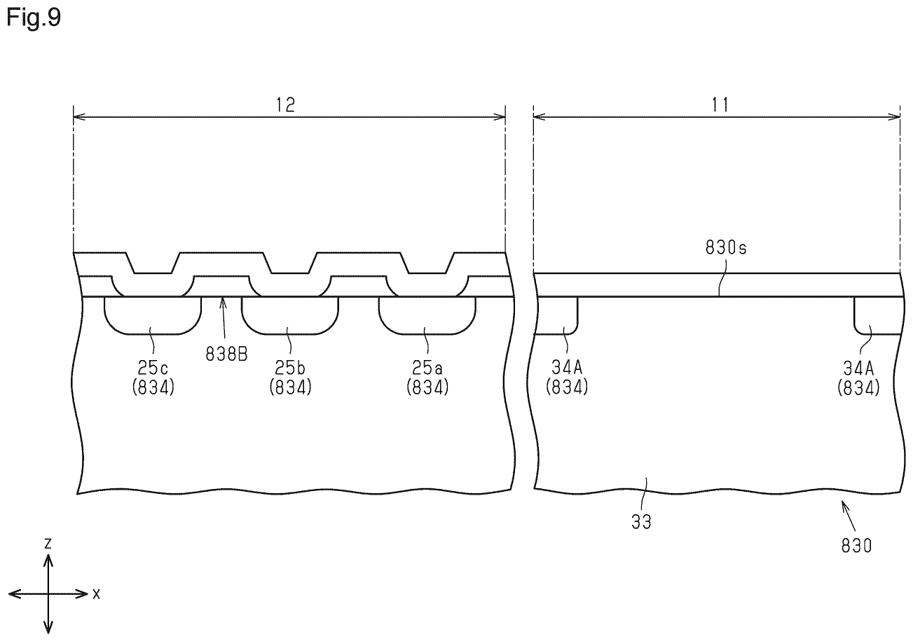

As illustrated in FIG. 9, the method for manufacturing the semiconductor device 10 according to the present embodiment includes a step of forming a p-type well region 834 as a semiconductor region of a second conductive type on the semiconductor substrate 830. Specifically, p-type impurities are selectively implanted into the substrate head surface 830s of the semiconductor substrate 830. Subsequently, the semiconductor substrate 830 is thermally treated to diffuse the p-type impurities. Through the above steps, the well region 834 is formed. The well region 834 is partially formed in the drift layer 33. The head surface of the well region 834 forms the substrate head surface 830s and is thus a head surface continuous with the head surface of the drift layer 33. The well region 834 includes the well region 34A and the guard rings 25a to 25d (guard ring 25d not shown in FIG. 9). The step of forming the well region 834 in the semiconductor substrate 830 corresponds to partially forming a second semiconductor region of a second conductive type on the first semiconductor layer. The well region 834 is covered by the substrate-side insulation film 838B.

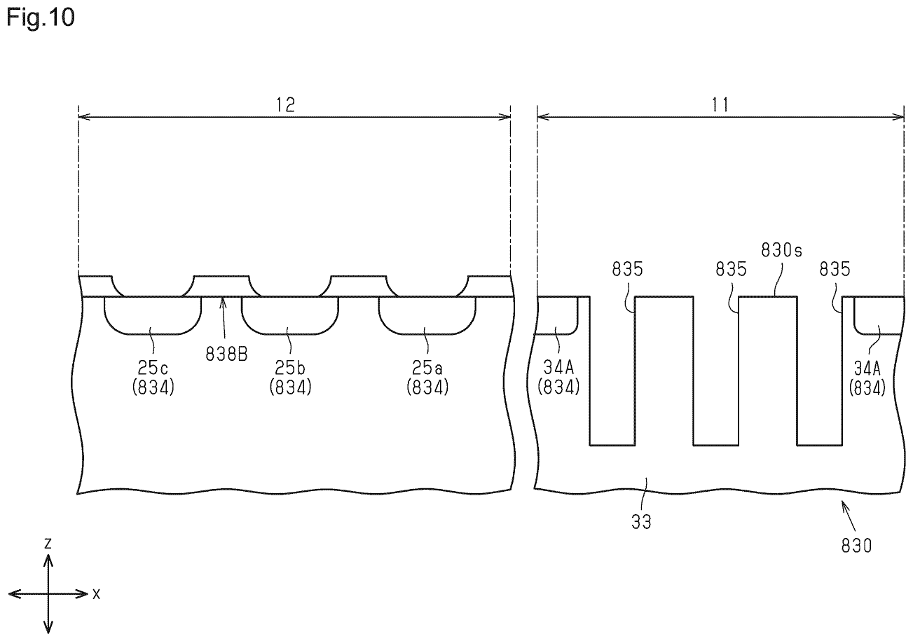

As illustrated in FIG. 10, the method for manufacturing the semiconductor device 10 according to the present embodiment includes a step of forming a plurality of trenches 835 in a portion of the semiconductor substrate 830 corresponding to the cell region 11. Specifically, a trench mask (not illustrated) is first formed on the substrate head surface 830s of the semiconductor substrate 830. Subsequently, the trench mask is etched selectively. That is, as viewed in the z-direction, a region of the trench mask where the trenches 835 are to be formed is etched. Thus, a region of the substrate head surface 830s of the semiconductor substrate 830 where the trenches 835 are to be formed is exposed from the trench mask. Subsequently, a region of the substrate head surface 830s of the semiconductor substrate 830 where the trenches 835 are to be formed is etched. This forms the trenches 835 in the semiconductor substrate 830.

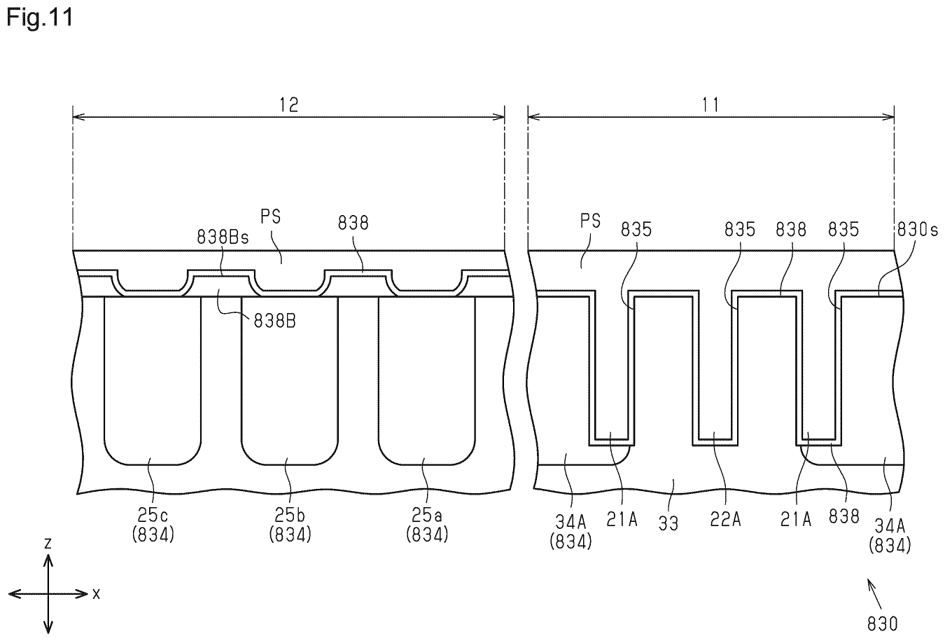

As illustrated in FIG. 11, the method for manufacturing the semiconductor device according to the present embodiment includes a step of forming an insulation film 838 and a step of forming an electrode.

In the step of forming the insulation film 838, the semiconductor substrate 830 is first thermally oxidized to form an oxide film on the entire head surface of the semiconductor substrate 830 including the wall surface of each trench 835. That is, the insulation film 838 is a silicon oxide film (SiO₂). This forms the insulation film 838 in the cell region 11 on the substrate head surface 830s of the semiconductor substrate 830. The insulation film 838 is an insulation film corresponding to the insulation film 38. The insulation film 838 in the cell region 11 is a gate insulation film and is also formed on the wall surface of each trench 835. In the peripheral region 12 of the semiconductor substrate 830, the insulation film 838 is stacked on a head surface 838Bs of the substrate-side insulation film 838B. In the present embodiment, the step of forming the substrate-side insulation film 838B and the insulation film 838 corresponds to forming a first insulation film.

Subsequently, in the step of forming an electrode, an electrode material PS such as polysilicon is embedded in each trench 835 and is formed on the substrate head surface 830s of the semiconductor substrate 830. This forms the gate trench 22A and the emitter trench 21A.

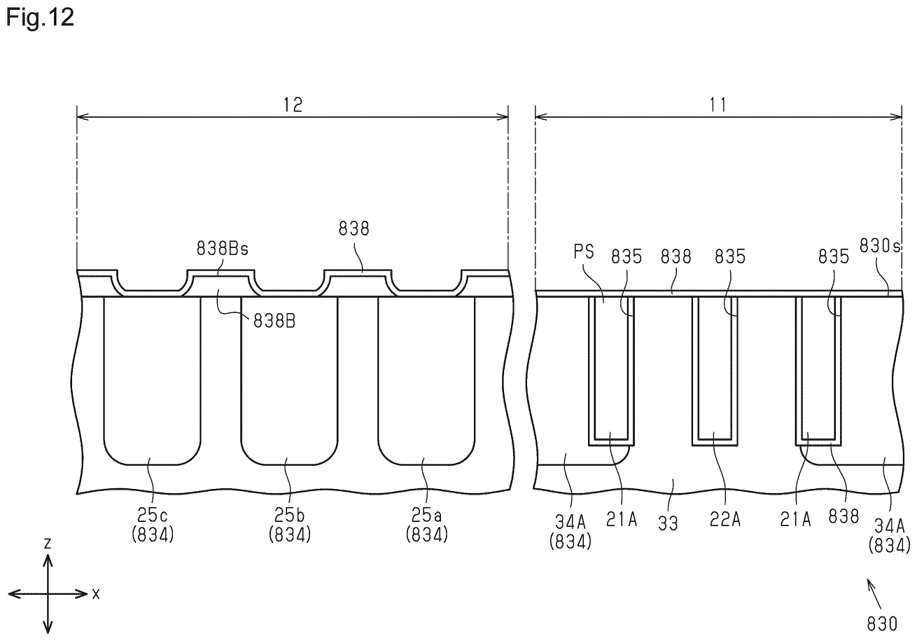

As illustrated in FIG. 12, the method for manufacturing the semiconductor device according to the present embodiment includes a step of etching the electrode material PS and a step of forming the insulation film 838 on the electrode material PS.

In the step of etching the electrode material PS, the electrode material PS on the substrate head surface 830s of the semiconductor substrate 830 is removed through etching. Although not illustrated, the electrode material PS of the gate fingers 23A and 23B in the peripheral region 12 and the gate electrode 22 and the electrode material PS of the internal interconnection 26b of the equipotential ring 26 are not etched.

Subsequently, in the step of forming the insulation film 838 on the electrode material PS, the electrode material PS embedded in each trench 835, the electrode material PS forming the gate fingers 23A and 23B and the gate electrode 22, and the electrode material PS forming the internal interconnection 26b of the equipotential ring 26 are oxidized. This forms the insulation film 838 on each electrode material PS. The electrode material PS of each of the gate fingers 23A and 23B is an element corresponding to the gate layer 23a. The insulation film 838 on the electrode material PS is a film corresponding to the oxide film 23c of each of the gate fingers 23A and 23B and the oxide film 26d of the internal interconnection 26b of the equipotential ring 26.

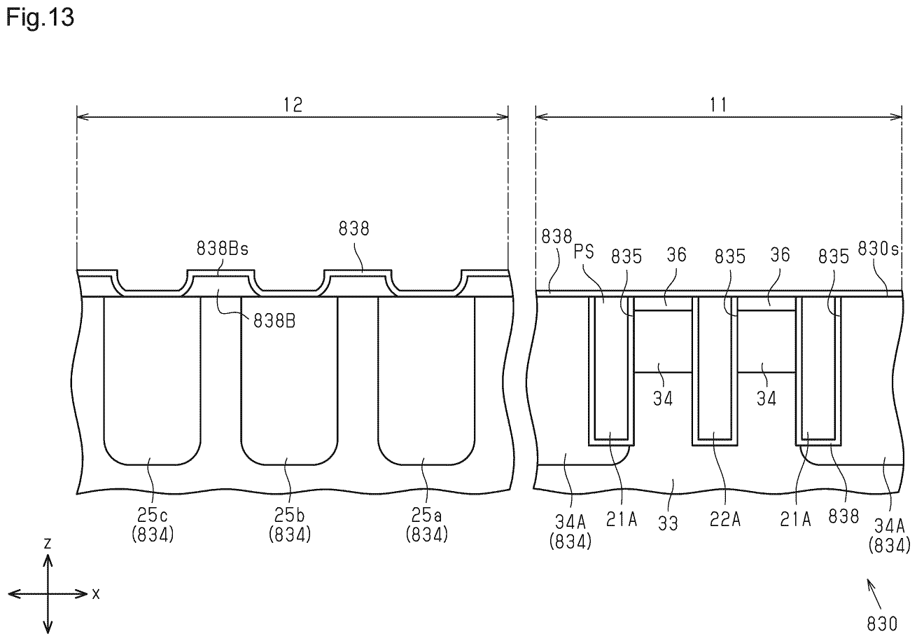

As illustrated in FIG. 13, the method for manufacturing the semiconductor device of the present embodiment includes a step of forming the base region 34, the emitter region 36, and the channel stop region 26a (refer to FIG. 7). Specifically, n-type and p-type dopants are selectively ion-implanted and diffused into a portion of the substrate head surface 830s of the semiconductor substrate 830 corresponding to the cell region 11. This sequentially forms the p-type base region 34, the n⁺-type emitter region 36, and the channel stop region 26a. That is, the emitter region 36 and the channel stop region 26a are formed in the same process.

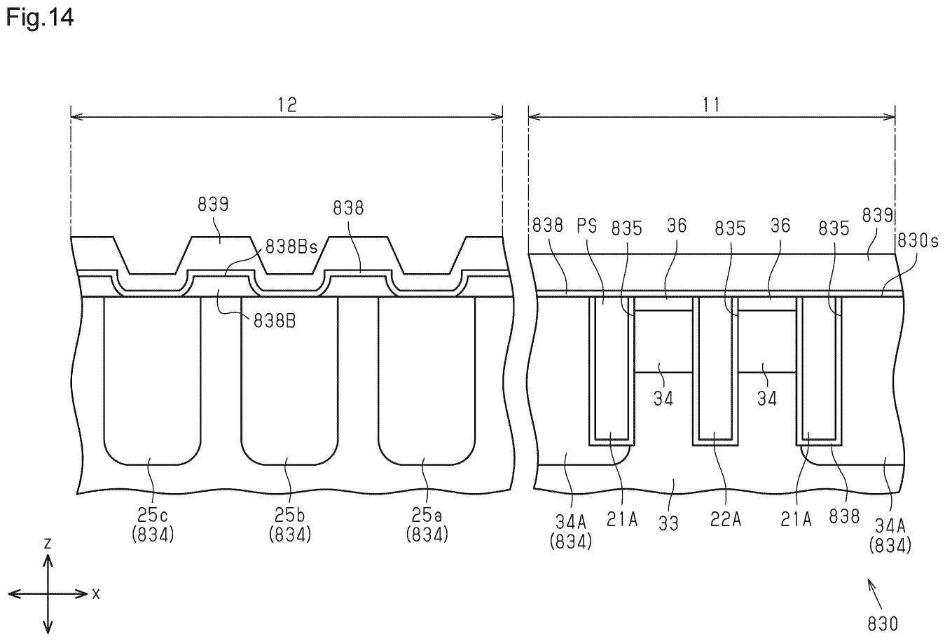

As illustrated in FIG. 14, the method for manufacturing the semiconductor device according to the present embodiment includes a step of forming an intermediate insulation film 839. The intermediate insulation film 839 is a silicon oxide film (SiO₂) formed over the entire substrate head surface 830s of the semiconductor substrate 830 through, for example, chemical vapor deposition (CVD). The intermediate insulation film 839 is an insulation film corresponding to the intermediate insulation film 39. The intermediate insulation film 839 is stacked on the insulation film 838. This forms an insulation film having a double-layer structure of the insulation film 838 and the intermediate insulation film 839 on the substrate head surface 830s of the semiconductor substrate 830 in the cell region 11. An insulation film having a triple-layer structure of the substrate-side insulation film 838B, the insulation film 838, and the intermediate insulation film 839 is formed on the substrate head surface 830s of the semiconductor substrate 830 in the peripheral region 12. As described above, in the present embodiment, the step of forming the substrate-side insulation film 838B, the insulation film 838, and the intermediate insulation film 839 corresponds to forming an insulation film covering a plurality of cells in a cell region and forming a peripheral insulation film covering the head surface of the first semiconductor layer and the head surface of the second semiconductor region. Further, in the present embodiment, the step of forming the substrate-side insulation film 838B, the insulation film 838, and the intermediate insulation film 839 corresponds to forming a peripheral insulation film with a silicon oxide film that covers the head surface of the first semiconductor layer and the head surface of the second semiconductor region.

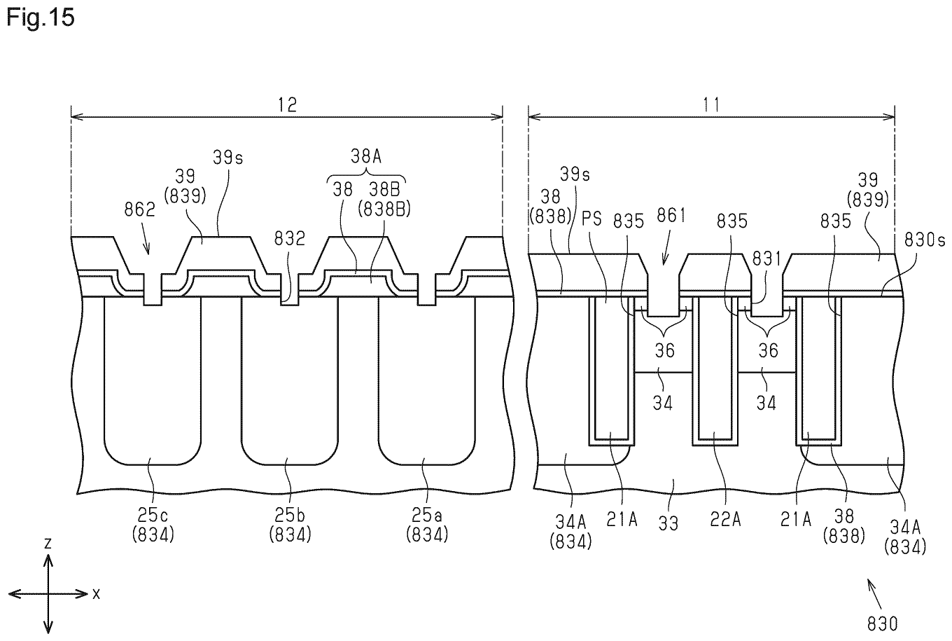

As illustrated in FIG. 15, the method for manufacturing the semiconductor device 10 according to the present embodiment includes a step of forming an opening.

In the cell region 11, openings 861 extending through the intermediate insulation film 839 and the insulation film 838 are formed through etching. The openings 861 in the cell region 11 expose the base region 34. The openings 861 form recesses 831 in the substrate head surface 830s of the semiconductor substrate 830 in correspondence with the base region 34.

In the peripheral region 12, openings 862 extending through the intermediate insulation film 839, the insulation film 838, and the substrate-side insulation film 838B are formed through etching. The openings 862 in the peripheral region 12 exposes each of the guard rings 25a to 25d, for example. The openings 862 form recesses 832 in the substrate head surface 830s of the semiconductor substrate 830 corresponding to the guard rings 25a to 25d. Other openings 862 may expose the well region 34A in correspondence with the gate fingers 23A and 23B or expose the well region 34A in correspondence with the emitter extension 24. The step of forming the opening corresponds to forming an opening that exposes part of the head surface of the second semiconductor region in the peripheral insulation film.

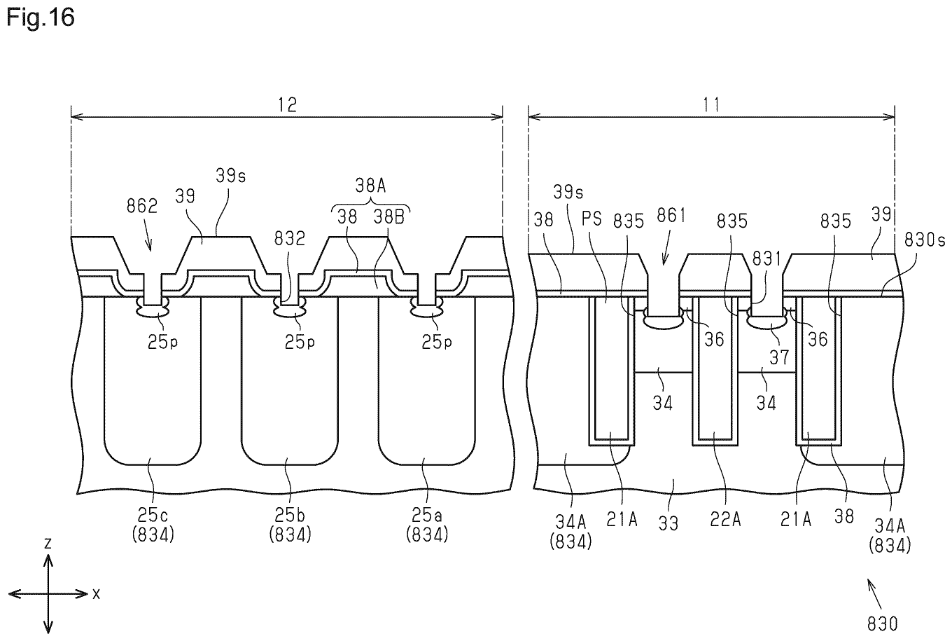

As illustrated in FIG. 16, the method for manufacturing the semiconductor device 10 according to the present embodiment includes a step of forming the base contact region 37 and the contact region 25p. Specifically, the p⁺-type base contact region 37 and the contact region 25p are each formed by ion-implanting and diffusing the p-type dopant into the substrate head surface 830s of the semiconductor substrate 830 through the openings. Although not illustrated, the method for manufacturing the semiconductor device 10 according to the present embodiment includes a step of forming the contact region 34B at a portion corresponding to the emitter extension 24 in the well region 34A exposed from the opening 862. This step is performed, for example, in the same step as the step of forming the base contact region 37 and the contact region 25p.

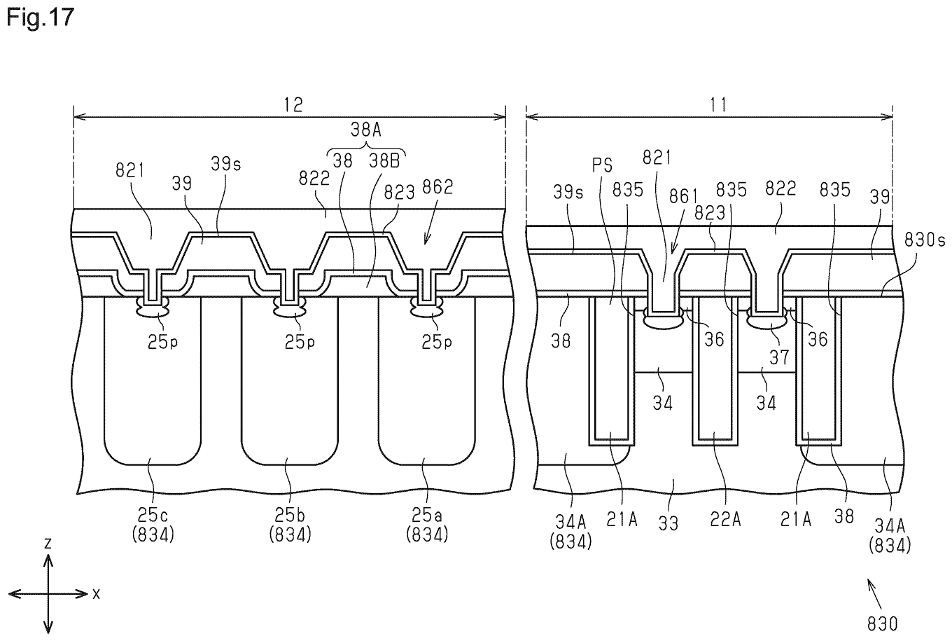

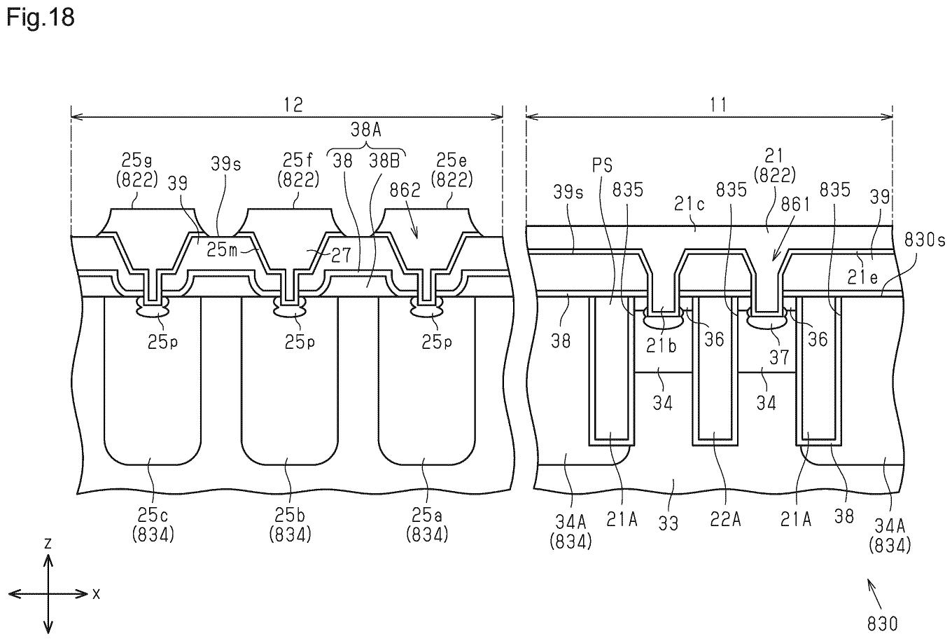

As illustrated in FIGS. 17 and 18, the method for manufacturing the semiconductor device 10 of the present embodiment includes a step of forming the emitter electrode 21, the gate electrode 22, the gate fingers 23A and 23B, the emitter extension 24, the field plates 25e to 25h, and the equipotential ring 26. In the present embodiment, the step of forming the emitter electrode 21, the gate electrode 22, the gate fingers 23A and 23B, the emitter extension 24, the field plates 25e to 25h, and the equipotential ring 26 corresponds to forming an electrode portion and forming a peripheral electrode portion. FIGS. 17 and 18 show the emitter electrode 21 and the field plates 25e to 25g.

As illustrated in FIG. 17, a first metal layer is formed on the head surface 39s of the intermediate insulation film 39 and the wall surface of each of the openings 861 and 862 through sputtering using titanium (Ti), for example. Subsequently, a second metal layer is formed on the first metal layer through sputtering using titanium nitride (TiN). This forms a barrier metal layer 823. The barrier metal layer 823 corresponds to the barrier metal layer 21e of the emitter electrode 21, the barrier metal layer 23m of the gate finger 23A (23B), the barrier metal layer 24m of the emitter extension 24, the barrier metal layers 25m of the field plates 25e to 25h, and the barrier metal layer 26m of the equipotential ring 26. That is, in the present embodiment, the barrier metal layers 21e, 23m, 24m, 25m, 26m are formed in the same step.

Subsequently, embedded electrodes 821 and an electrode layer 822 are formed integrally through sputtering using AlCu. The embedded electrodes 821 are the portions embedded in each of the openings 861 and 862. The electrode layer 822 is formed over the entire intermediate insulation film 39 as viewed in the z-direction.

Subsequently, as illustrated in FIG. 18, the electrode layer 822 is etched to form the electrode layer 822 corresponding to the electrode layer 21f of the emitter electrode 21, the electrode layer 23n of the gate electrode 22 and the gate fingers 23A and 23B, the electrode layer 24n of the emitter extension 24, the electrode layer 24n of the field plates 25e to 25h, and the electrode layer 26n of the equipotential ring 26. That is, in the present embodiment, the electrode layers 21f, 23n, 24n, 25n, 26n are formed in the same step. In addition, the embedded electrodes 21b and the electrode main body 21c of the emitter electrode 21, the gate electrode 22, the embedded electrodes 23ba and the interconnection main body 23bb of each of gate fingers 23A and 23B, the embedded electrodes 24a and the interconnection main body 24b of the emitter extension 24, the embedded electrodes 27 and the plate main body 28 of each of the field plates 25e to 25h, and the embedded electrodes 26f and 26g and the interconnection main body 26i of the equipotential ring 26 are formed in the same step. FIG. 18 illustrates the emitter electrode 21 and the electrode layer 822 corresponding to each of the field plates 25e to 25g.

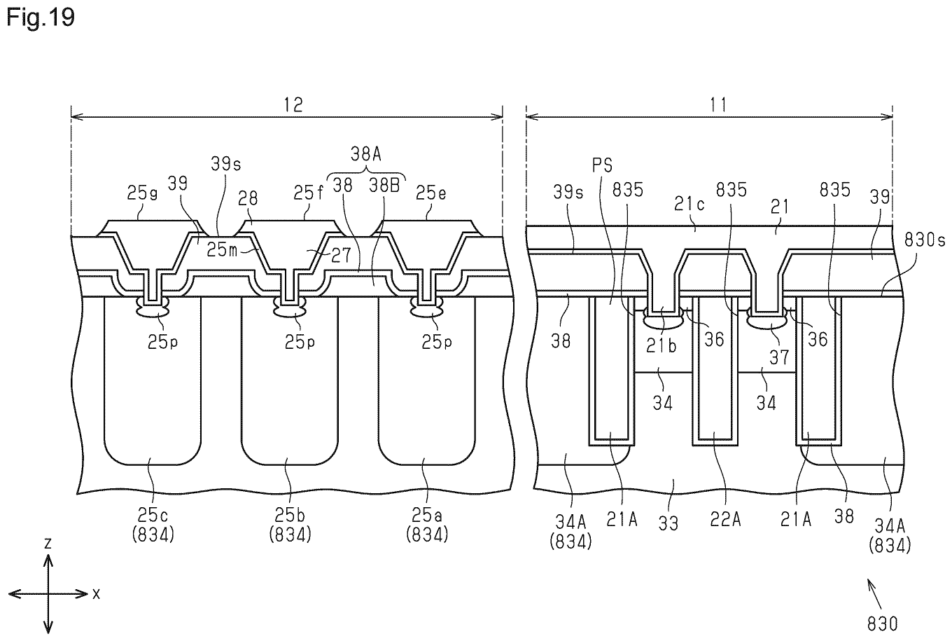

Subsequently, as illustrated in FIG. 19, the electrode layer 822, which corresponds to the emitter extension 24, the field plates 25e to 25h, and the equipotential ring 26, is reduced in thickness by, for example, etching the electrode layer 822 corresponding to the emitter electrode 21, the gate electrode 22, the gate fingers 23A and 23B, the emitter extension 24, the field plates 25e to 25h, and the equipotential ring 26. In the present embodiment, the electrode layer 822 is etched to have a thickness of 2 μm or less, for example. This forms the emitter extension 24, the field plates 25e to 25h, and the equipotential ring 26. FIG. 19 illustrates the field plates 25e to 25g. As described above, the step of forming a peripheral electrode portion includes a step of setting the thickness of the electrode layer 822 corresponding to the insulation film 38A and the intermediate insulation film 39 in the electrode layer 822 to less than the thickness of the electrode layer 822 corresponding to the insulation film 38 and the intermediate insulation film 39.

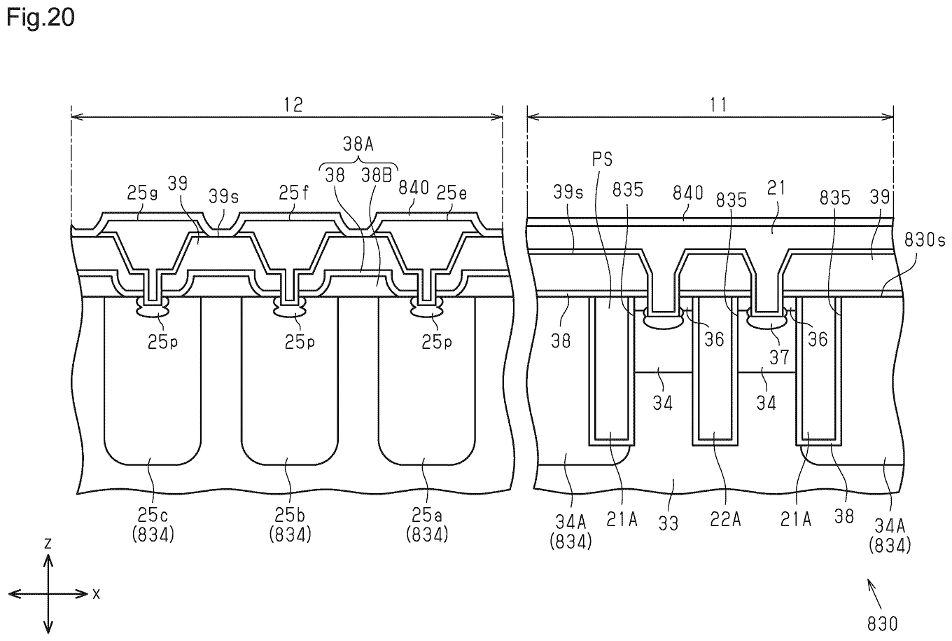

As illustrated in FIG. 20, the method for manufacturing the semiconductor device 10 according to the present embodiment includes a step of forming a barrier layer 840. The barrier layer 840 is an insulation layer corresponding to the barrier layer 40 of the semiconductor device 10. The barrier layer 840 is formed from a material having a smaller diffusion coefficient than the intermediate insulation film 839 and the insulation film 838, 838B. In the present embodiment, in the peripheral region 12, the barrier layer 840 is formed from a material containing silicon nitride (SiN) entirely over the head surface 39s of the intermediate insulation film 39, the gate fingers 23A and 23B, the emitter extension 24, the field plates 25e to 25h, and the equipotential ring 26 by CVD, for example. This forms the barrier layer 840 that is stepped. In the present embodiment, the step of forming the barrier layer 840 corresponds to forming a barrier layer that is stepped and has a smaller diffusion coefficient than the peripheral insulation film to cover both the peripheral insulation film and the projection. The step of forming the barrier layer 840 corresponds to forming a barrier layer that is stepped with a silicon nitride film to cover both the peripheral insulation film and the projection.

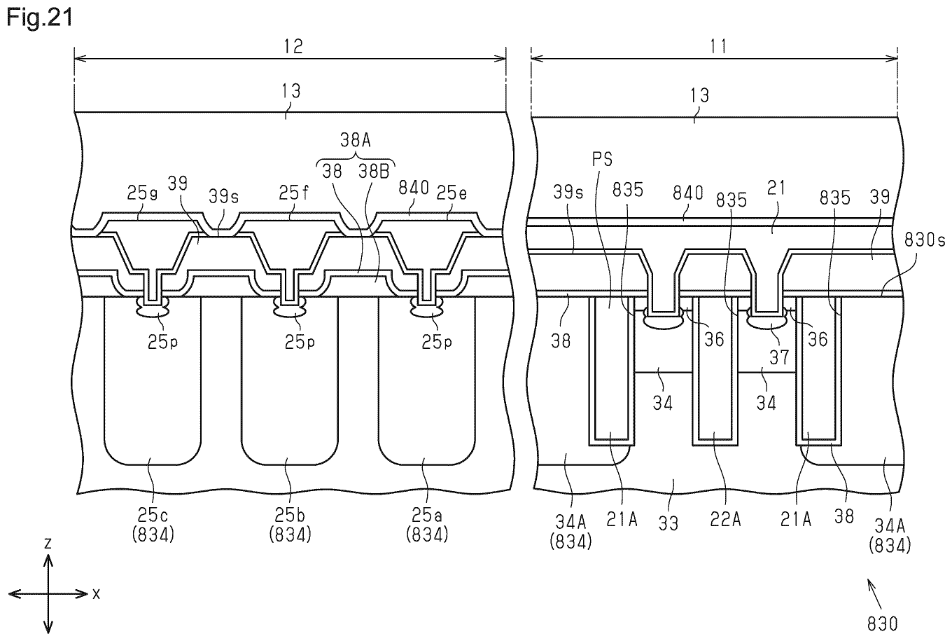

As illustrated in FIG. 21, the method for manufacturing the semiconductor device according to the present embodiment includes a step of forming the passivation film 13. Specifically, a passivation layer of a material having a larger diffusion coefficient than the barrier layer 840, for example, an organic material such as polyimide, is formed over the entire substrate head surface 830s of the semiconductor substrate 830 as viewed in the z-direction to cover the emitter electrode 21, the gate electrode 22, the gate fingers 23A and 23B, the field plates 25e to 25h, and the equipotential ring 26. Subsequently, an opening is formed through etching to expose the emitter electrode 21 and the gate electrode 22. This forms the passivation film 13, the emitter electrode pad 16, and the gate electrode pad 17. The passivation film 13 covers the barrier layer 40. In the present embodiment, the step of forming the passivation film 13 corresponds to forming a passivation film having a larger diffusion coefficient than the barrier layer on the barrier layer. Further, the step of forming the passivation film 13 corresponds to forming a passivation film formed of an organic insulation film on the barrier layer.

Although not illustrated, the method for manufacturing the semiconductor device according to the present embodiment includes a step of forming the buffer layer 32, the collector layer 31, and the collector electrode 29. Specifically, the buffer layer 32 and the collector layer 31 are formed sequentially by selectively ion-implanting and diffusing n-type and p-type dopants with respect to the substrate back surface of the semiconductor substrate 830. Subsequently, the collector electrode 29 is formed on the surface of the collector layer 31 at the side opposite the buffer layer 32. The semiconductor device 10 is manufactured through the above steps. FIGS. 8 to 21 illustrate some of the manufacturing steps of the semiconductor device 10, and the method for manufacturing the semiconductor device 10 may include steps that are not illustrated in FIGS. 8 to 21.

Operation of First Embodiment

The operation of the semiconductor device 10 according to the present embodiment will now be described.

The passivation film 13, which is an organic insulation film such as polyimide, is formed over the entire device main surface 10s for protection from external ions. That is, the passivation film 13 covers the entire peripheral region 12. The passivation film 13, however, has a large diffusion coefficient. Thus, external ions may be diffused in and passed through the passivation film 13.

When the intermediate insulation film 39 and the insulation films 38 and 38A, which are silicon oxide films, are charged by the external ions passing through the passivation film 13, in particular, when the intermediate insulation film 39 and the insulation film 38A in the peripheral region 12 (e.g., the FLR 25) are charged by the external ions, the electric field spreads differently in each of the guard rings 25a to 25d. Thus, the breakdown voltage may become lower than the preset breakdown voltage.

A barrier layer having a silicon nitride film with a small diffusion coefficient may be used so that the intermediate insulation film 39 and the insulation films 38 and 38A are not charged by external ions. In one example, when the FLR 25 includes a barrier layer, the barrier layer may be formed on, for example, the head surface 39s of the intermediate insulation film 39 and the head surfaces of the field plates 25e to 25h.

However, the head surfaces of the field plates 25e to 25h and the head surface 39s of the intermediate insulation film 39 are located at different positions in the z-direction. from each other. Thus, the portion of the barrier layer between the head surface 39s of the intermediate insulation film 39 and the head surfaces of the field plates 25e to 25h will be stepped. A crack may form when the stepped portion of the barrier layer is large. The formation of cracks may result in external ions entering the intermediate insulation film 39 through the cracks and charging the intermediate insulation film.

In the present embodiment, the field plates 25e to 25h are formed so that the thickness T1 of the projection 28a is less than the thickness T2 of the electrode main body 21c of the emitter electrode 21. Thus, the stepped form of the barrier layer 40 covering the projection 28a is smaller than the stepped form (not illustrated in FIG. 3) of the barrier layer 40 covering the electrode main body 21c of the emitter electrode 21. This limits the formation of cracks in the stepped portion of the barrier layer 40 and limits charging of the intermediate insulation film 39 that would be caused by external ions when cracks form.

### Advantages of First Embodiment

The semiconductor device 10 of the present embodiment has the advantages described below.

(1-1) The cell region 11 of the semiconductor device 10 includes the emitter electrode 21 with the electrode main body 21c on the intermediate insulation film 39. Each of the field plates 25e to 25h respectively contacting the guard rings 25a to 25d includes the projection 28a on the intermediate insulation film 39. The semiconductor device 10 includes the intermediate insulation film 39, the barrier layer 40, which is stepped to cover the field plates 25e to 25h at the projections 28a and which has a smaller diffusion coefficient than the intermediate insulation film 39 and the insulation film 38, and a passivation film 13, which is stacked on the barrier layer 40 and has a larger diffusion coefficient than the barrier layer 40. The thickness T1 of the projection 28a is less than the thickness T2 of the electrode main body 21c.

This configuration limits the formation of cracks at the stepped portions of the barrier layer 40 covering the field plates 25e to 25h. This limits the passage of external ions through the barrier layer 40 that would occur when cracks are formed. As a result, the intermediate insulation film 39 will not be charged by such external ions. This limit changes in the potential at the guard rings 25a to 25d that would occur when the intermediate insulation film 39 is charged. Thus, the dielectric strength of the semiconductor device 10 will not decrease. In the same manner, cracking at the stepped portions of the barrier layer 40 will be limited in the gate fingers 23A and 23B, the emitter extension 24, and the equipotential ring 26. This limits the passage of external ions through the barrier layer 40 that would occur when cracking occurs.

(1-2) The thickness T1 of the projection 28a of each of the field plates 25e to 25h is less than the total thickness T3 of the thickness T6 of the insulation film 38A and the thickness T4 of the intermediate insulation film 39.

With this configuration, cracking will be limited in the stepped portions of the barrier layer 40 covering the field plates 25e to 25h. This limits the passage of external ions through the barrier layer 40 that would occur when cracking occurs.

(1-3) In each of the field plates 25e to 25h, the projection 28a is integrated with the embedded electrode 27.

This allows the field plates 25e to 25h to be formed through fewer steps than when the projection 28a is formed separately from the embedded electrode 27 in each of the field plates 25e to 25h. This simplifies the manufacturing process of the field plates 25e to 25h.

(1-4) The projections 28a of the field plates 25e to 25h cover the edges of the guard rings 25a to 25d as viewed in the z-direction.

With this configuration, the stepped portions of the barrier layer 40 covering the field plates 25e to 25h are located outward from the edges of the guard rings 25a to 25d as viewed in the z-direction. Therefore, even if cracks occur in the stepped portions of the barrier layer 40, external ions are less likely to enter the guard rings 25a to 25d.

(1-5) The projections 28a of the field plates 25e to 25h have portions extending beyond the edges of the guard rings 25a to 25d as viewed in the z-direction.

With this configuration, the stepped portions of the barrier layer 40 covering the field plates 25e to 25h are located outward from and separated from the edges of the guard rings 25a to 25d as viewed in the z-direction. Therefore, even if cracks form in the stepped portions of the barrier layer 40, external ions that enter the guard rings 25a to 25d will be limited.

(1-6) The projection 28a of each of the field plates 25e to 25h includes the inclined surface 28b that is inclined so that the intermediate insulation film 39 becomes closer as the sideward end of the projection 28a becomes closer.

With this configuration, each of the stepped portions of the barrier layer 40 covering the field plates 25e to 25h is shapes in conformance with the inclined surface 28b. Thus, the barrier layer 40 bends gradually at the stepped portions of the barrier layer 40 This limits the formation of cracks at the stepped portions of the barrier layer 40.

(1-7) The field plate 25e includes the head surface 25s, which is the part of the field plate 25e that is the farthest from the intermediate insulation film 39, and the curved surface 28c, which connects the head surface 25s and the inclined surface 28b. The field plates 25f to 25h also have the same shape.

With this configuration, the shape of the barrier layer 40 covering the curved surface 28c of the field plate 25e is curved. Thus, the barrier layer 40 bends gradually. This limits the formation of cracks in the stepped portions of the barrier layer 40. In the same manner, the formation of cracks will be limited in the stepped portions of the barrier layer covering the field plates 25f to 25h.

(1-8) The inclined surfaces 28b of the projections 28a of the field plates 25e to 25h are curved.

This configuration allows the part of the stepped portion covering the intermediate insulation film 39 and the inclined surface 28b to be small and thereby limits cracking.

(1-9) The thickness T5 of the barrier layer 40 is less than the thickness T1 of the projection 28a of each of the field plates 25e to 25h.

This configuration allows the semiconductor device 10 to be reduced in thickness. In addition, even though the barrier layer 40 is thin, the thickness T1 of the projection 28a of each of the field plates 25e to 25h is less than the thickness T2 of the electrode main body 21c of the emitter electrode 21. This limits the formation of cracks in the stepped portions of the barrier layer 40.

(1-10) The insulation film 38 and the intermediate insulation film 39 are both silicon oxide films. The passivation film 13 is an organic insulation film containing polyimide, and the barrier layer 40 is a silicon nitride film.

With this configuration, the diffusion coefficient of the barrier layer 40 is smaller than that of the insulation film 38, the intermediate insulation film 39, and the passivation film 13. This results in the same advantage as advantage (1-1).

(1-11) The method for manufacturing a semiconductor device 10 includes preparing the semiconductor substrate 830 on which the n⁻-type drift layer 33 is formed, partially forming the p-type well region 834 in the drift layer 33, forming the insulation film 838 and the intermediate insulation film 839 on the substrate head surface 30s of the semiconductor substrate 30, forming the emitter electrode 21 having the electrode main body 21c on the intermediate insulation film 39, forming an opening that exposes a portion of the head surface of the well region 834 in the insulation film 838 and the intermediate insulation film 839, forming the field plates 25e to 25h, each including the projection 28a that projects sideward from the opening on the intermediate insulation film 839, in which the field plates 25e to 25h contact a portion of the well region 834 exposed from the opening, forming the barrier layer 840 having a smaller diffusion coefficient than the insulation film 838 and the intermediate insulation film 839 with a stepped form so as to cover both the intermediate insulation film 839 and the field plates 25e to 25h, and stacking the passivation film 13, having a larger diffusion coefficient than the barrier layer 40, on the barrier layer 840. In the step of forming the field plates 25e to 25h, the thickness T1 of the projection 28a is less than the thickness T2 of the electrode main body 21c. This results in the same advantage as the advantage (1-1).

### Second Embodiment

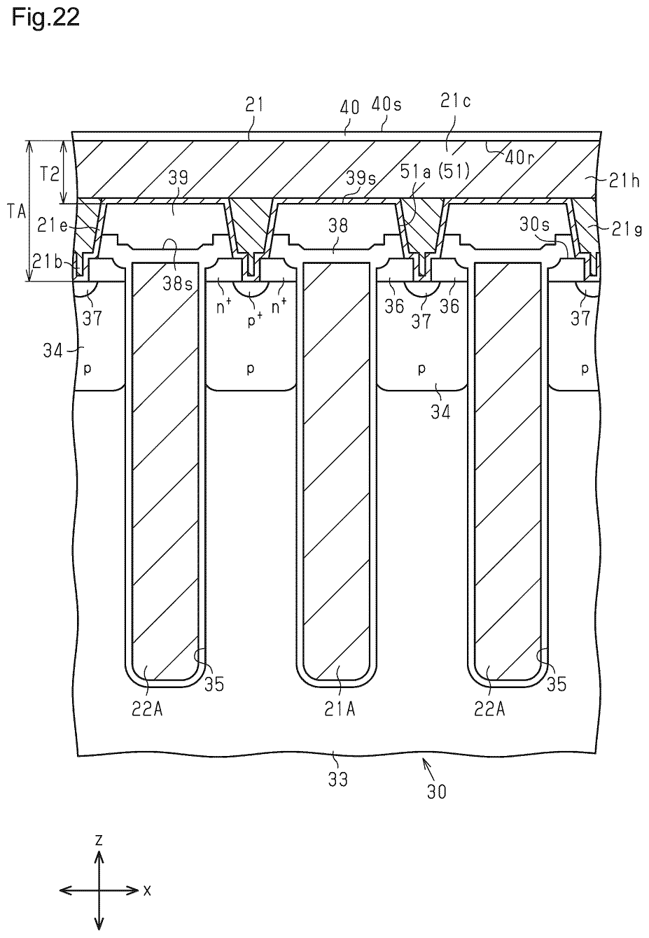

A semiconductor device 10 according to a second embodiment will now be described with reference to FIGS. 22 to 37. The semiconductor device 10 of the present embodiment differs from the semiconductor device 10 of the first embodiment in the interconnection structure and the insulation film structure. The following description will focus on the differences from the semiconductor device 10 of the first embodiment. Same reference numerals are given to those components that are the same as the corresponding components in the semiconductor device 10 of the first embodiment. Such components will not be described in detail.

Structure of Semiconductor Device

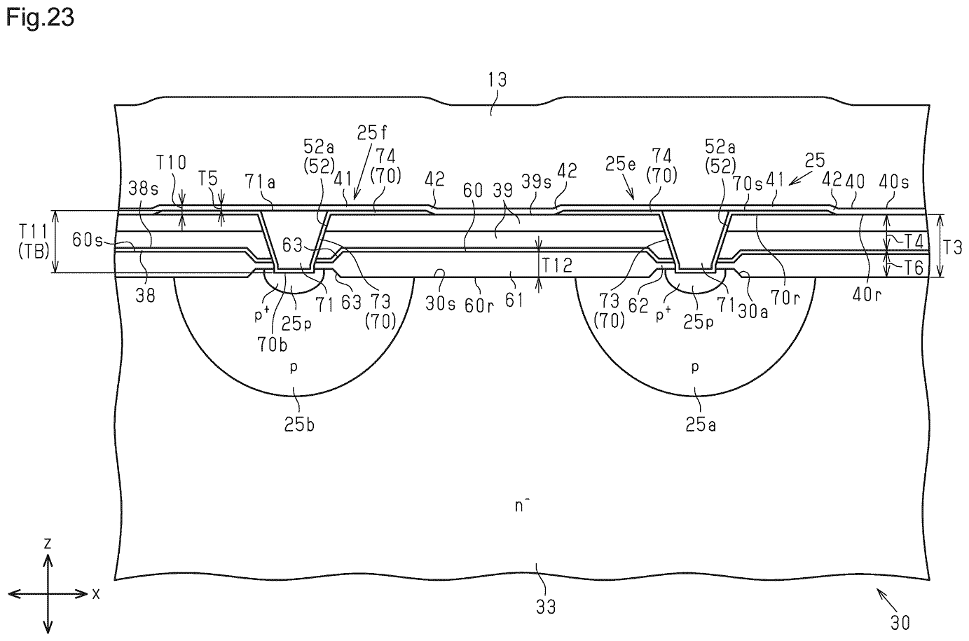

The structure of the semiconductor device according to the present embodiment will now be described with reference to FIGS. 22 and 23.

FIG. 22 illustrates part of the cross-sectional structure of the cell region 11. As illustrated in FIG. 22, the cell region 11 of the present embodiment differs from that of the first embodiment in the interconnection structure of the emitter electrode 21. Therefore, the interconnection structure of the emitter electrode 21 will hereafter be described in detail. Same references numerals are given to those elements that are the same as the corresponding elements of the first embodiment. Such elements will not be described in detail.

As illustrated in FIG. 22, the emitter electrode 21 has an embedded electrode 21b and an electrode main body 21c which are formed individually. That is, unlike the first embodiment, the emitter electrode 21 includes a first electrode layer 21g corresponding to the embedded electrode 21b and a second electrode layer 21h corresponding to the electrode main body 21c.

The first electrode layer 21g is embedded in a hole surrounded by the barrier metal layer 21e. The first electrode layer 21g is formed from a material containing tungsten (W), for example. In the present embodiment, the upper end surface of the first electrode layer 21g is flush with the upper end surface of the barrier metal layer 21e.

The electrode main body 21c is formed on the embedded electrode 21b. The electrode main body 21c is stacked on the head surface 39s of the intermediate insulation film 39 in the same manner as the first embodiment. The second electrode layer 21h contacts both the upper end surface of the first electrode layer 21g and the upper end surface of the barrier metal layer 21e. The thickness T2 of the electrode main body 21c is the same as the thickness T2 (refer to FIG. 3) of the first embodiment. The thickness TA of the emitter electrode 21 is the same as the thickness TA (refer to FIG. 3) of the first embodiment.

FIG. 23 illustrates part of the cross-sectional structure of the FLR 25. The interconnection structure and the insulation film structure of each of the gate fingers 23A and 23B and the emitter extension 24 (refer to FIG. 4) are similar to those of the FLR 25 and thus will not be described.

As illustrated in FIG. 23, a local oxidation of silicon (LOCOS) oxide film 60 is formed on the substrate head surface 30s of the semiconductor substrate 30 instead of the substrate-side insulation film 38B. That is, in the present embodiment, the insulation film 38A includes the stacked structure of the LOCOS oxide film 60 and the insulation film 38. The LOCOS oxide film 60 has a head surface 60s and a back surface 60r at opposite sides in the z-direction. The back surface 60r of the LOCOS oxide film 60 contacts the substrate head surface 30s of the semiconductor substrate 30.

The LOCOS oxide film 60 includes a thick film portion 61, a thin film portion 62, and an inclined portion 63.

The thick film portion 61 is a relatively thick portion of the LOCOS oxide film 60 and located, for example, between adjacent ones of the peripheral openings 52. The thin film portion 62 is a relatively thin portion of the LOCOS oxide film 60 overlapping a peripheral opening 52, for example, as viewed in the z-direction. Thus, the peripheral opening 52 is arranged in the thin film portion 62 of the LOCOS oxide film 60. The inclined portion 63 is located between the thick film portion 61 and the thin film portion 62 so as to connect the thick film portion 61 and the thin film portion 62. The inclined portion 63 is inclined so that the thickness of the LOCOS oxide film 60 between the head surface and the back surface 60r increases from the thin film portion 62 toward the thick film portion 61.

The thick film portion 61 projects into the substrate head surface 30s of the semiconductor substrate 30. This forms a recess 30a where the substrate head surface 30s is recessed in the semiconductor substrate 30. The configuration of the LOCOS oxide film 60 can be changed freely. In one example, the thin film portion 62 may be omitted from the LOCOS oxide film 60. In this case, the LOCOS oxide film 60 will be formed by separated oxide films, each including the thick film portion 61 and the inclined portion 63.

In the present embodiment, the insulation film 38 is formed on the head surface of the LOCOS oxide film 60. The insulation film 38 on the LOCOS oxide film 60 is shaped in conformance with the LOCOS oxide film 60. That is, the insulation film 38 is shaped to be inclined in conformance with the inclined portion 63 of the LOCOS oxide film 60. In the present embodiment, the insulation film 38 is formed over the entire head surface 60s of the LOCOS oxide film 60. The intermediate insulation film 39 is formed on the head surface 38s of the insulation film 38. Therefore, the intermediate insulation film 39 entirely covers the thick film portion 61, the thin film portion 62, and the inclined portion 63 of the LOCOS oxide film 60. In the present embodiment, the intermediate insulation film 39 is a stack of two layers.

In the present embodiment, the peripheral opening 52 extends through the intermediate insulation film 39, the insulation film 38, and the LOCOS oxide film 60. Thus, the guard ring 25a is exposed from the intermediate insulation film 39, the insulation film 38, and the LOCOS oxide film 60 through the peripheral opening 52. In the present embodiment, the peripheral opening 52 extends through the thin film portion 62 of the LOCOS oxide film 60.

The field plate 25e includes an electrode layer 70, which is formed on the head surface 39s of the intermediate insulation film 39 and the wall surface 52a of the insulation film 38A and the intermediate insulation film 39 defining the peripheral opening 52, and an embedded electrode 71, which is embedded in the peripheral opening 52. In the present embodiment, the electrode layer 70 and the embedded electrode 71 are formed separately. The electrode layer 70 is formed from a material containing titanium nitride (TiN), and the embedded electrode 71 is formed from a material containing tungsten (W), for example. The electrode layer 70 is a barrier metal layer.

The electrode layer 70 has an electrode head surface 70s and an electrode back surface 70r facing opposite directions. The electrode head surface 70s is a surface facing the same direction as the head surface 39s of the intermediate insulation film 39, and the electrode back surface 70r is a surface facing the intermediate insulation film 39. In the present embodiment, the electrode back surface 70r contacts the head surface 39s of the intermediate insulation film 39.

The electrode layer 70 includes an open-side electrode layer 73, which contacts the wall surface 52a of the peripheral opening 52 and the head surface of the guard ring 25a (substrate head surface 30s of the semiconductor substrate 30), and a projection 74, which extends outside the peripheral opening 52. In the present embodiment, the open-side electrode layer 73 is integrated with the projection 74.

The projection 74 is a portion covering the intermediate insulation film 39 as viewed in the z-direction. As viewed in the z-direction, the projection 74 forms a portion of the field plate 25e extending outside the peripheral opening 52 in a direction orthogonal to the direction in which the field plate 25e extends, that is, a portion extending outside the peripheral opening 52 in the width direction of the field plate 25e. In the present embodiment, the projection 74 covers the entire guard ring 25a as viewed in the z-direction. Part of the projection 74 extends beyond the edge of the guard ring 25a as viewed in the z-direction. The projection 74 covering the guard ring 25a and the projection 74 covering the guard ring 25b are spaced apart from each other.

The thickness TB of the field plate 25e is less than the thickness TA of the emitter electrode 21 in the same manner as the first embodiment.

In the present embodiment, the electrode layer 70 has a constant thickness T10. Thus, the projection 74 has a constant thickness.

The thickness T10 of the electrode layer 70 is less than the thickness T2 of the electrode main body 21c of the emitter electrode 21. The thickness T10 of the electrode layer 70 is less than a thickness T11 of the embedded electrode 71. The thickness T10 of the electrode layer 70 is less than the thickness T4 of the intermediate insulation film 39. The thickness T10 of the electrode layer 70 is less than a thickness T12 of the thick film portion 61 of the LOCOS oxide film 60. The thickness T10 of the electrode layer 70 is, for example, 2 μm or less, and preferably less than 1 μm. The thickness T10 of the electrode layer 70 is, for example, 50 nm or greater. In the present embodiment, the thickness T10 of the electrode layer 70 is approximately 100 nm.

The thickness T10 of the electrode layer 70 is the thickness of the projection 74 that is the portion of the electrode layer 70 formed on the head surface 39s of the intermediate insulation film 39. The thickness T10 is the distance in the z-direction between the electrode head surface 70s and the electrode back surface 70r at the projection 74. In the present embodiment, the thickness T10 of the electrode layer 70 is an average thickness when the thickness of the projection 74 is measured at a number of locations in the projection 74 of the electrode layer 70.

The definition of the thickness T10 of the electrode layer 70 is not limited to the average thickness, and may be changed as follows. The thickness T10 of the electrode layer may be the maximum thickness when the thickness of the electrode layer 70 is measured at a number of locations in the electrode layer 70 or may be the minimum thickness when the thickness of the electrode layer 70 is measured at a number of locations in the electrode layer 70.

The thickness T11 of the embedded electrode 71 is the distance between the bottom surface 70b of the electrode layer 70 formed on the head surface of the guard ring 25a (substrate head surface 30s of semiconductor substrate 30) and an upper end surface 71a of the embedded electrode 71. In the present embodiment, the thickness T11 of the embedded electrode 71 is an average thickness when the thickness of the embedded electrode 71 is measured at a plurality of location of the embedded electrode 71. In the present embodiment, the thickness T11 of the embedded electrode 71 is the same as the thickness TB of the field plate 25e.

The thickness T12 of the thick film portion 61 is the distance between the head surface 60s of the thick film portion 61 and the back surface 60r that is opposite to the head surface 60s. The back surface 60r contacts the recess 30a of the semiconductor substrate 30. That is, the thickness T12 of the thick film portion 61 is the distance between the substrate head surface 30s in the recess 30a of the semiconductor substrate 30 and the head surface of the thick film portion 61. The thickness T12 of the thick film portion 61 is an average thickness when the thickness of the thick film portion 61 is measured at a number of locations.

The definition of the thickness T11 of the embedded electrode 71 is not limited to the average thickness, and may be changed as follows. The thickness T11 of the embedded electrode 71 may be the maximum thickness when the thickness of the embedded electrode 71 is measured at a number of locations in the embedded electrode 71 or may be the minimum thickness when the thickness of the embedded electrode 71 is measured at a number of locations in the embedded electrode 71.

Even if the thickness T10 of the electrode layer 70 is defined as the maximum thickness when the thickness of the electrode layer 70 is measured at a number of locations in the electrode layer 70, and the thickness T11 of the embedded electrode 71 is defined as the minimum thickness when the thickness of the embedded electrode 71 is measured at a number of locations, the thickness T10 of the electrode layer 70 is preferably less than the thickness T11 of the embedded electrode 71.

The definition of the thickness T12 of the thick film portion 61 is not limited to the average thickness, and may be changed as follows. The thickness T12 of the thick film portion 61 may be the maximum thickness when the thickness of the thick film portion 61 is measured at a number of locations in the thick film portion 61 or may be the minimum thickness when the thickness of the thick film portion 61 is measured at a number of locations in the thick film portion 61.

The barrier layer 40 is stepped and covers both the intermediate insulation film 39 and the field plate 25e. That is, the barrier layer 40 includes the plate cover portion 41 that covers the field plate 25e. The steps 42 are formed at locations where the plate cover portion 41 covers each end of the electrode layer 70 in the width direction. Each step 42 is formed at a boundary between the intermediate insulation film 39 and the distal end of the projection 74 of the field plate 25e in the barrier layer 40. The projection 74 extends beyond the edge of the guard ring 25a as viewed in the z-direction. Thus, the step 42 is located outward from the edge of the guard ring 25a.

The plate cover portion 41 of the barrier layer 40 is shaped in conformance with the head surface shape of the electrode layer 70 and the upper end surface 71a of the embedded electrode 71. The passivation film 13 is stacked on the barrier layer 40.

In the present embodiment, the thickness T5 of the barrier layer 40 is greater than the thickness T10 of the electrode layer 70. The thickness T5 of the barrier layer 40 is greater than or equal to the thickness of the thin film portion 62 of the LOCOS oxide film 60. The thickness T5 of the barrier layer 40 is less than the thickness of the thick film portion 61 of the LOCOS oxide film 60. The thickness T5 of the barrier layer 40 is not limited and may be, for example, less than the thickness of the thin film portion 62 of the LOCOS oxide film 60, or less than the thickness T10 of the electrode layer 70.

Method for Manufacturing Semiconductor Device

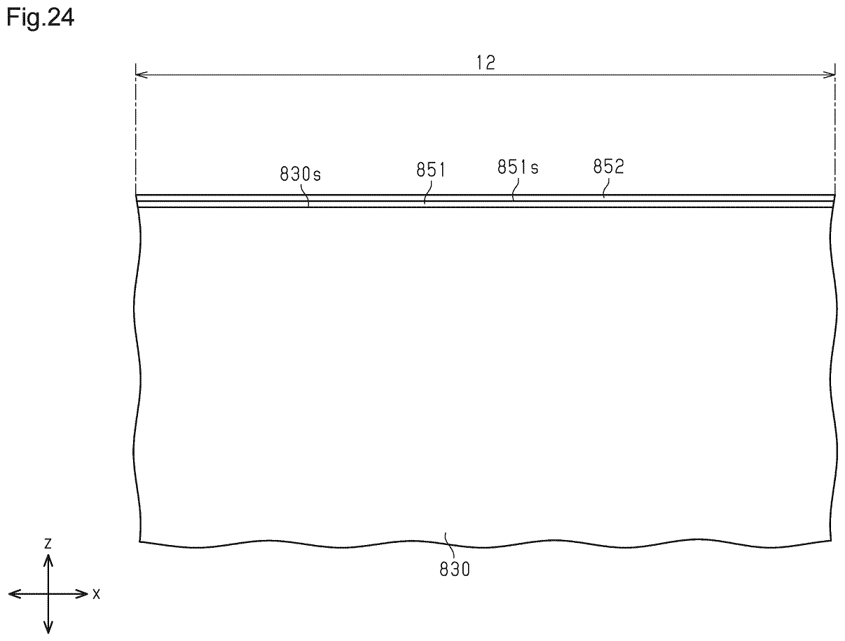

A method for manufacturing the semiconductor device 10 according to the present embodiment will now be described with reference to FIGS. 24 to 37. The method for manufacturing the semiconductor device 10 according to the present embodiment differs from the method for manufacturing the semiconductor device 10 according to the first embodiment in how an insulation film is formed on the substrate head surface 830s of the semiconductor substrate 830 and how an electrode is formed. Therefore, the following description will focus on the differences from the first embodiment. Manufacturing steps that are the same as the first embodiment will not be described. For the sake of brevity, the description of the method for manufacturing the semiconductor device 10 according to the present embodiment will focus on the steps for forming the cell region 11 and the FLR 25.

As illustrated in FIGS. 24 to 26, the method for manufacturing the semiconductor device 10 according to the present embodiment includes a step of forming the LOCOS oxide film 850.

As illustrated in FIG. 24, a semiconductor substrate 830 formed from a material containing Si is first prepared. A drift layer 33 is formed on the semiconductor substrate 830. Subsequently, an oxide film 851 is formed over the entire substrate head surface 830s of the semiconductor substrate 830 through, for example, CVD. The oxide film 851 includes, for example, a silicon oxide film (SiO₂ film). Subsequently, a mask 852 is formed over the entire head surface 851s of the oxide film 851 through, for example, CVD. The mask 852 includes, for example, a silicon nitride film (Si₃N₄ film).

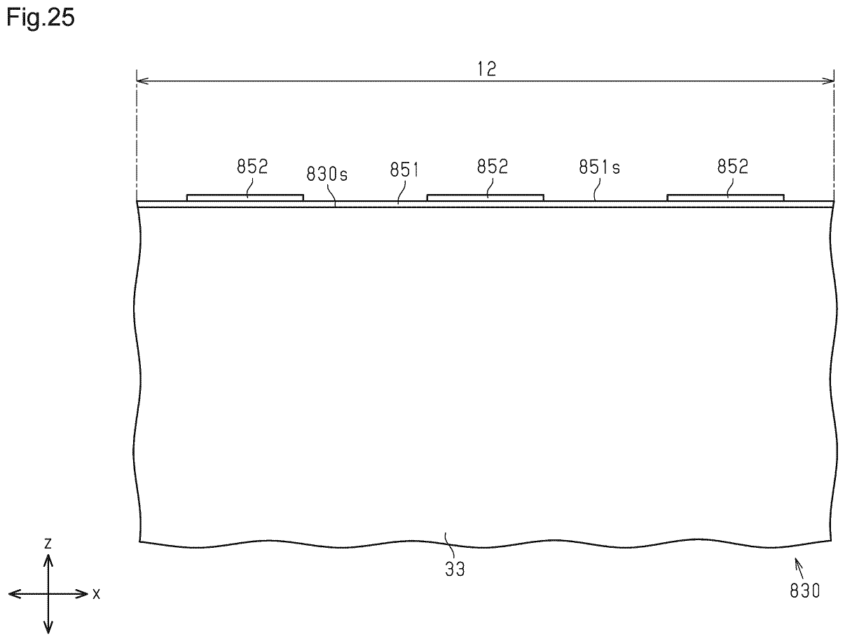

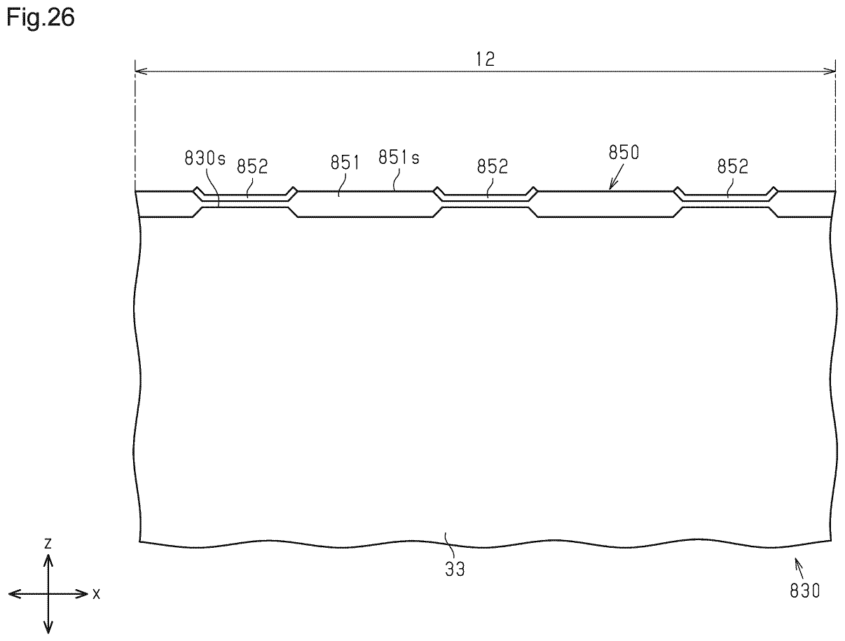

Next, as illustrated in FIG. 25, the mask 852 is etched selectively. This partially exposes the oxide film 851 from the mask 852. Thus, the mask 852 is formed on a part of the head surface of the drift layer 33. Subsequently, as illustrated in FIG. 26, the oxide film 851 is grown thermally. This increases the thickness of a portion of the oxide film 851 that is not covered with the mask 852. In a portion of the oxide film 851 covered with the mask 852, the oxide film 851 is not thermal grown. As a result, the oxide film 851 becomes partially thick. The above steps form the LOCOS oxide film 850. Subsequently, the mask 852 is removed.

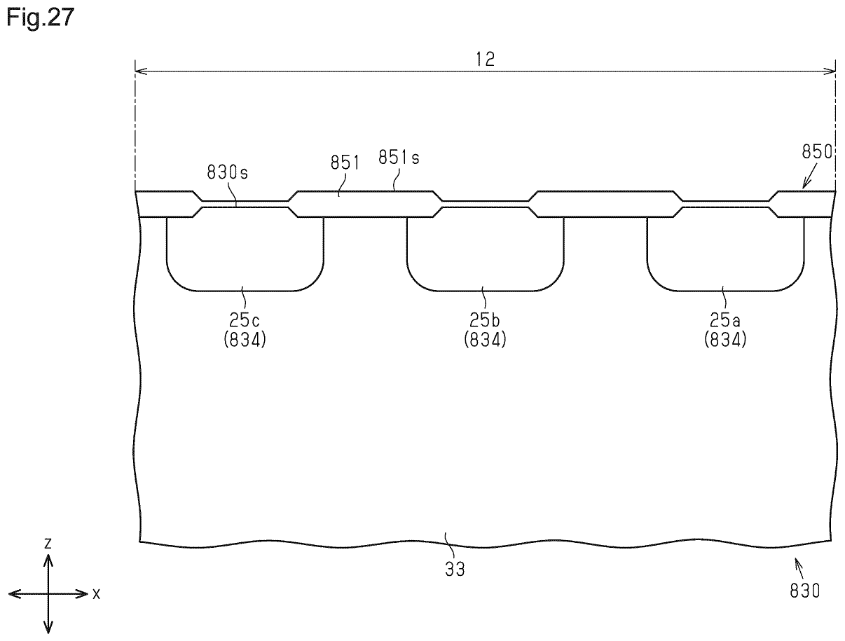

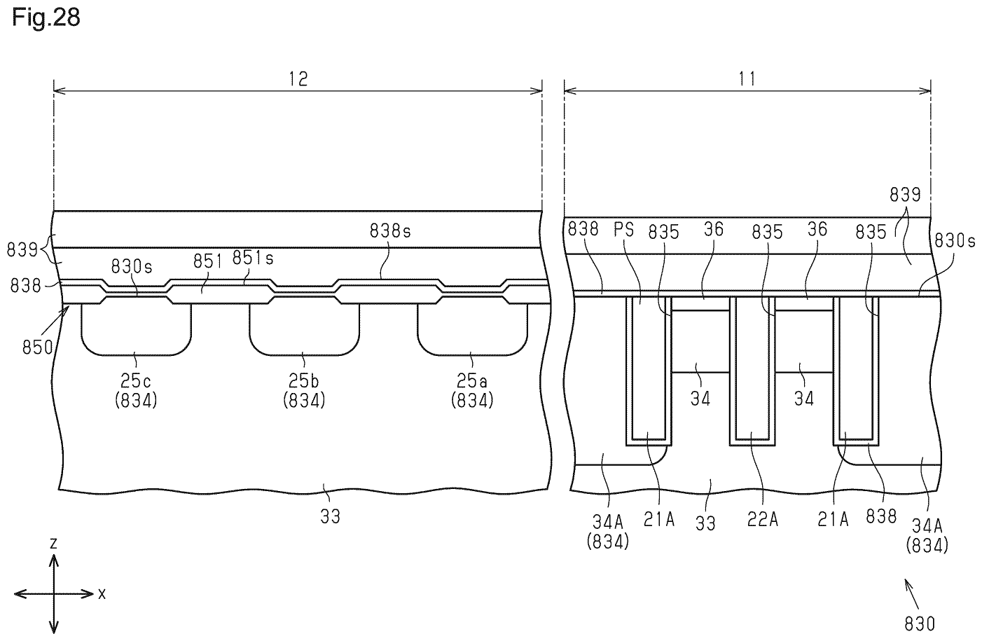

As illustrated in FIG. 27, the method for manufacturing the semiconductor device of the present embodiment includes a step of forming a p-type well region 834 that is a semiconductor region of a second conductive type. Specifically, p-type impurities are selectively implanted into the substrate head surface 830s of the semiconductor substrate 830. Subsequently, the semiconductor substrate 830 is thermally treated to diffuse p-type impurities. This forms the well region 834. The well region 834 includes a well region 34A (refer to FIG. 28) and guard rings 25a to 25d. FIG. 27 illustrates the guard rings 25a to 25c.

Although not illustrated, the method for manufacturing the semiconductor device according to the present embodiment includes a step of forming the trench 835, the insulation film 838, the gate trench 22A and the emitter trench 21A, the base region 34, the emitter region 36, and the channel stop region 26a in the cell region 11 in the same manner as in the first embodiment. The insulation film 838 is formed over both the cell region 11 and the peripheral region 12. The insulation film 838 in the peripheral region 12 is formed on the head surface 851s of the oxide film 851 (refer to FIG. 28).

As illustrated in FIG. 28, the method for manufacturing the semiconductor device according to the present embodiment includes a step of forming an intermediate insulation film 839. The step for forming the intermediate insulation film 839 is similar to that of the first embodiment. The intermediate insulation film 839 is formed on a head surface 838s of the insulation film 838. In the present embodiment, the step of forming the insulation film 838 and the intermediate insulation film 839 corresponds to forming an insulation film covering a plurality of cells in a cell region. The step of forming the LOCOS oxide film 850, the insulation film 838, and the intermediate insulation film 839 corresponds to forming a peripheral insulation film covering the head surface of the first semiconductor layer and the head surface of the second semiconductor region.

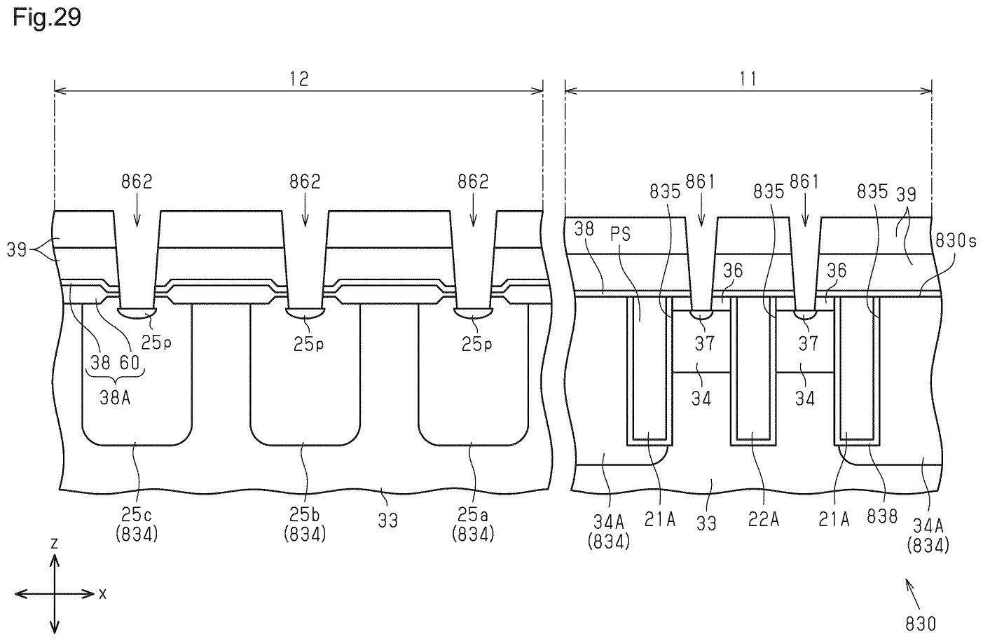

As illustrated in FIG. 29, the method for manufacturing the semiconductor device according to the present embodiment includes a step of forming the openings 861, 862, and a step of forming the base contact region 37 and the contact regions 34B and 25p. The step for forming the openings 861 and 862 is similar to that of the first embodiment. This forms the LOCOS oxide film 60, the insulation film 38, and the intermediate insulation film 39. The step for forming the base contact region 37 and the contact regions 34B and 25p is similar to that in the first embodiment. FIG. 29 illustrates the base contact region 37 and the contact region 25p.

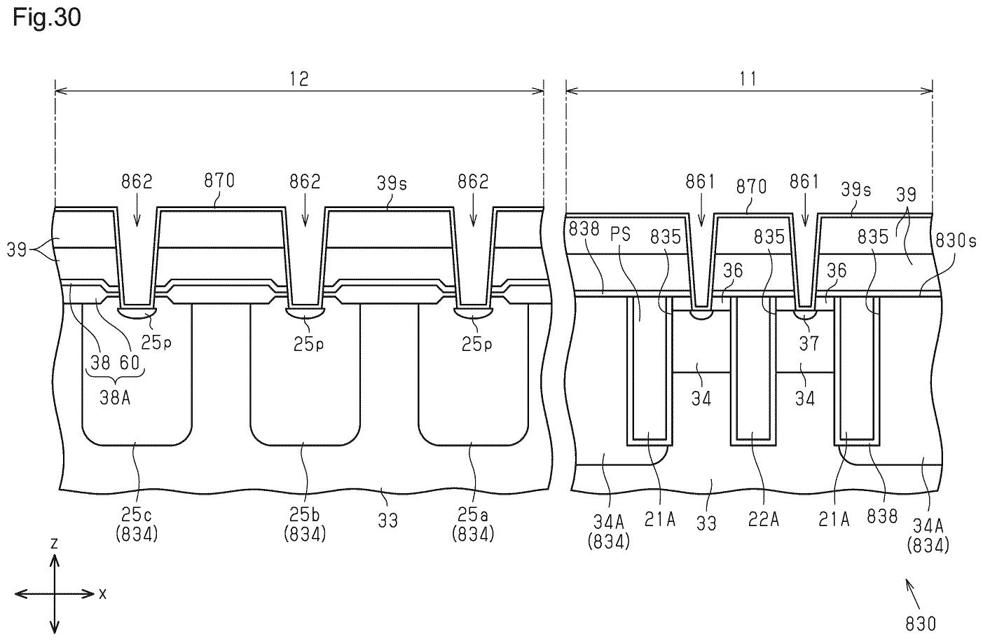

As illustrated in FIG. 30, the method for manufacturing the semiconductor device according to the present embodiment includes a step of forming a first electrode layer 870. The first electrode layer 870 is a member corresponding to the electrode layer 70 and the barrier metal layer 21e. The first electrode layer 870 is formed from a material containing Ti or TiN, for example, and is formed on the head surface 39s of the intermediate insulation film 39 and in the openings 861 and 862 through sputtering, for example. Therefore, the first electrode layer 870 is formed to contact the base contact region 37, which is exposed from the opening 861, and the contact region 25p of each of the guard rings 25a to 25d. The first electrode layer 870 is formed over the entire head surface 39s of the intermediate insulation film 39. As described above, in the step of forming the first electrode layer 870, the first electrode layer 870 is formed in each of the cell region 11 and the peripheral region 12. That is, the step of forming the first electrode layer 870 when forming the emitter electrode 21 is performed in the same step as the step of forming the first electrode layer 870 when forming the gate fingers 23A and 23B, the emitter extension 24, the field plates 25e to 25h, and the equipotential ring 26.

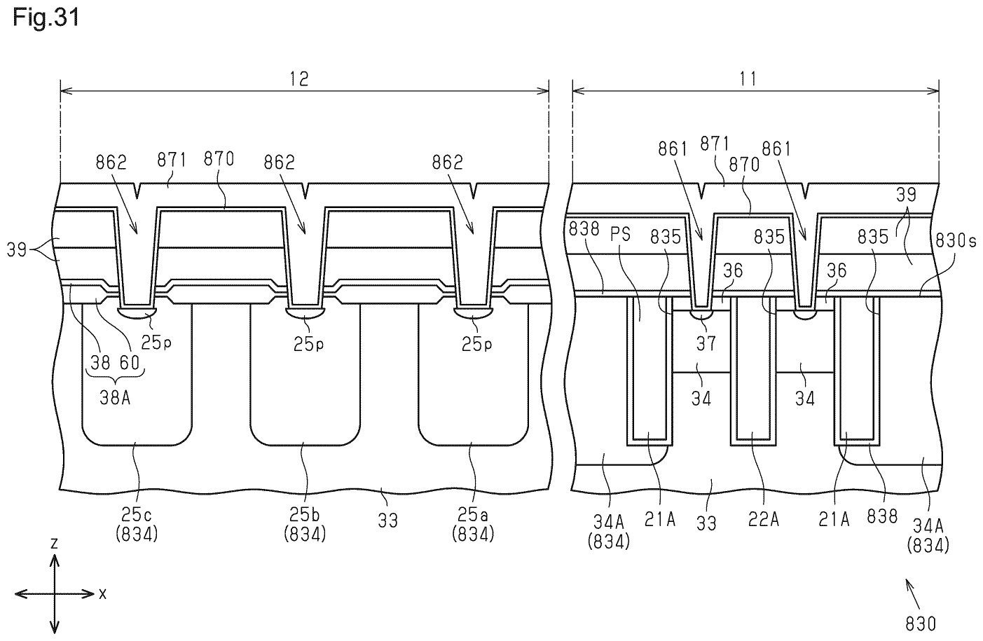

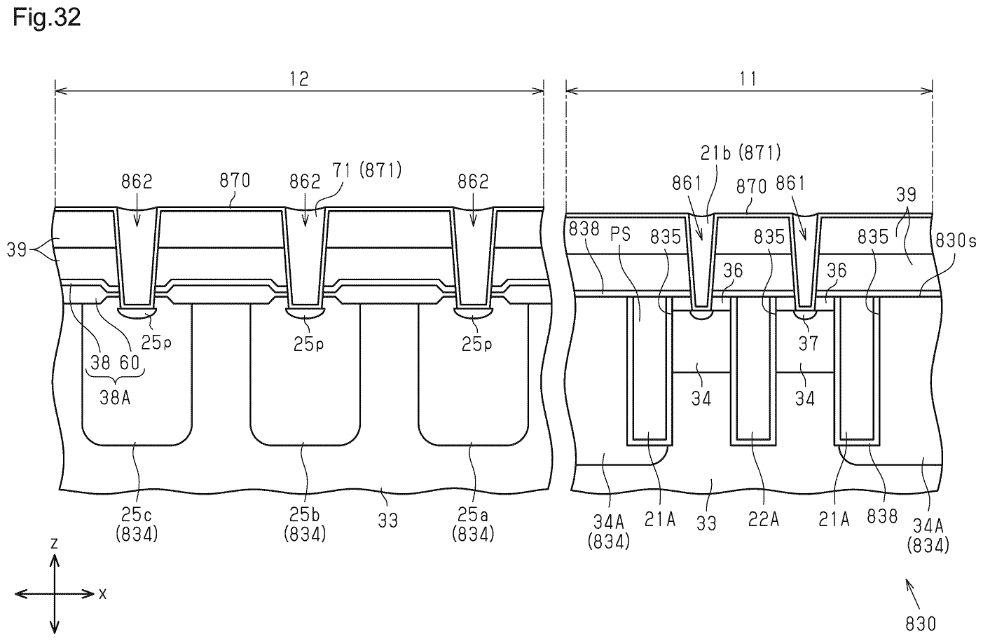

As illustrated in FIGS. 31 and 32, the method for manufacturing the semiconductor device 10 according to the present embodiment includes a step of forming the embedded electrode 871. The embedded electrode 871 is a member corresponding to the embedded electrodes 21b and 71.

As illustrated in FIG. 31, the embedded electrode 871 is formed from a material containing tungsten (W) on the first electrode layer 870 through CVD, for example. The embedded electrode 871 is embedded in each of the openings 861 and 862 and is formed above each of the openings 861 and 862.

Subsequently, as illustrated in FIG. 32, the embedded electrode 871 is etch-backed. This forms the embedded electrode 21b in the cell region 11 and the embedded electrode 71, which corresponds to each of the guard rings 25a to 25d. As described above, in the step of forming the embedded electrode 871, the embedded electrode 871 is formed in each of the cell region 11 and the peripheral region 12. That is, the step of forming the embedded electrode 871 when forming the emitter electrode 21 is performed in the same step as the step of forming the embedded electrode 871 when forming the gate fingers 23A and 23B, the emitter extension 24, and the field plates 25e to 25h.

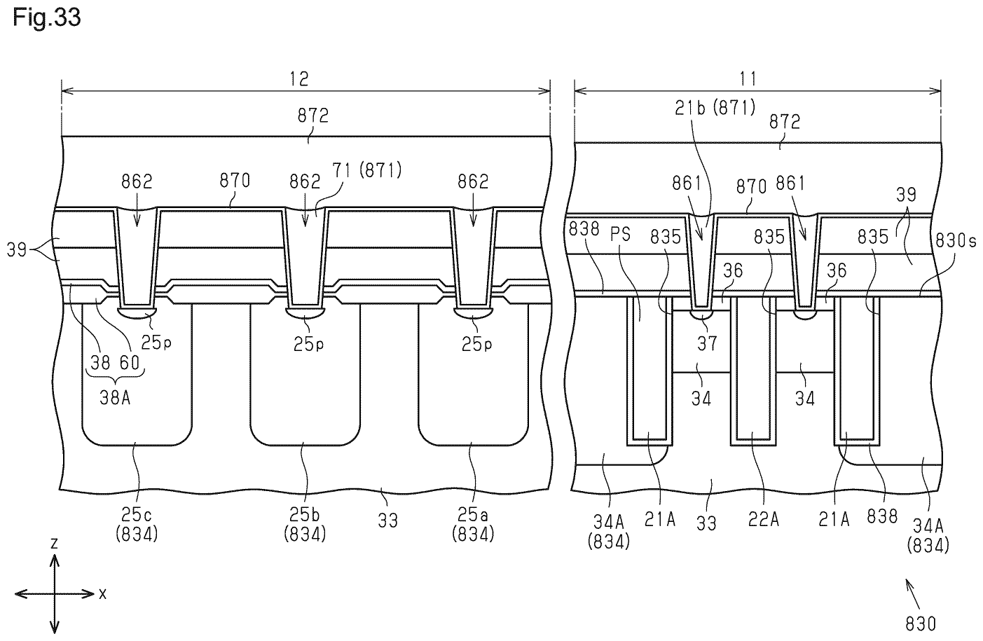

As illustrated in FIG. 33, the method for manufacturing the semiconductor device according to the present embodiment includes a step of forming a second electrode layer 872. The second electrode layer 872 is a member corresponding to the electrode main body 21c. The second electrode layer 872 is formed from a material containing AlCu on the first electrode layer 870 and the embedded electrode 71 through sputtering, for example. As shown in FIG. 33, the second electrode layer 872 has a greater thickness than the first electrode layer 870. As described above, in the step of forming the second electrode layer 872, the second electrode layer 872 is formed in each of the cell region 11 and the peripheral region 12. That is, the step of forming the second electrode layer 872 when forming the emitter electrode 21 is performed in the same step as the step of forming the second electrode layer 872 when forming the gate fingers 23A and 23B, the emitter extension 24, the field plates 25e to 25h, and the equipotential ring 26.

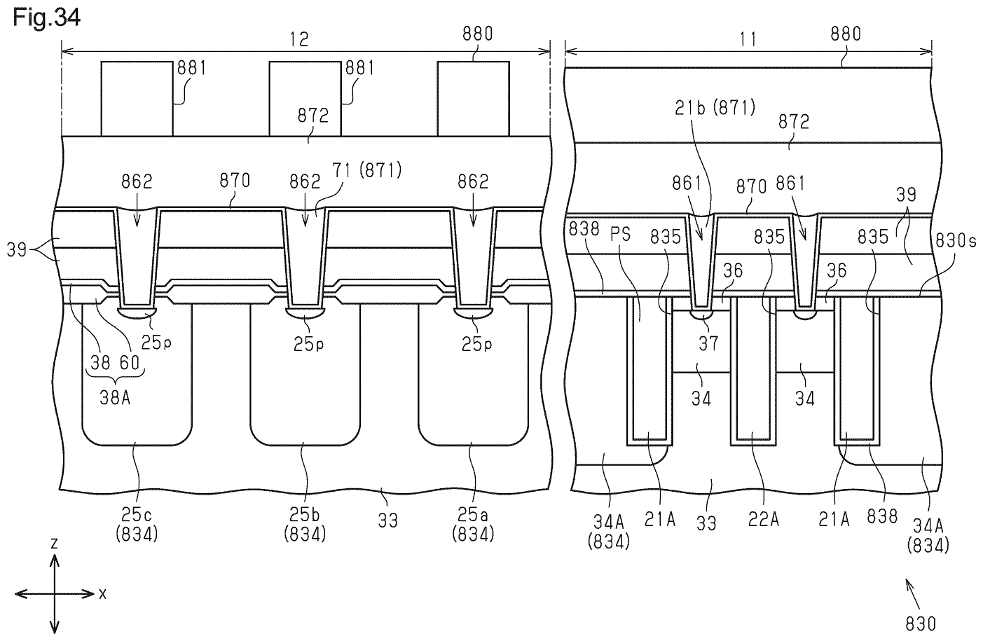

As illustrated in FIGS. 34 to 37, the method for manufacturing the semiconductor device 10 according to the present embodiment includes a step of etching the second electrode layer 872 in the peripheral region 12.

As illustrated in FIG. 34, a mask 880 is formed on the second electrode layer 872. Openings 881 are formed in a portion of the mask 880 covering the peripheral region 12. The second electrode layer 872 is exposed from the openings 881. In FIG. 34, the mask 880 is formed on the second electrode layer 872 at each portion where the field plates 25e to are formed. Although not illustrated, the mask 880 is also formed at a portion where the field plate 25h is formed.

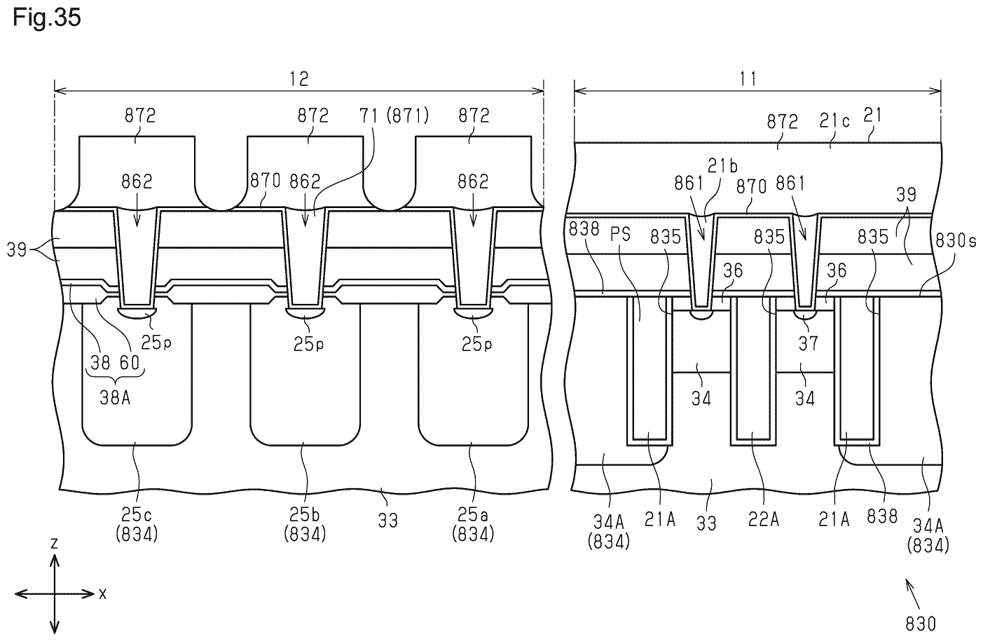

Subsequently, as illustrated in FIG. 35, the second electrode layer 872 exposed from each opening 881 is etched. The opening 881 is thus formed in conformance with the outer shape of the emitter electrode 21 in the second electrode layer 872 covering the cell region 11. Thus, the electrode main body 21c is formed by etching the second electrode layer 872.

This forms the emitter electrode 21. In the second electrode layer 872 covering the peripheral region 12, the second electrode layer 872 is etched through the opening 881, and the first electrode layer 870 exposed from each opening 881 is then etched. This forms the electrode layer 70. Then, the mask 880 is removed. FIG. 35 illustrates a state in which the mask 880 has been removed.

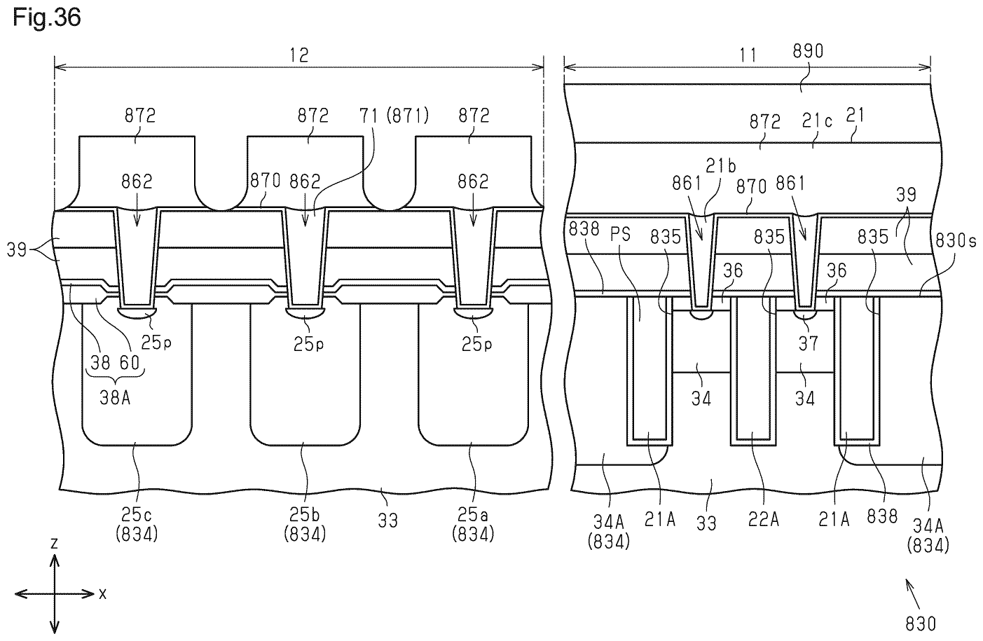

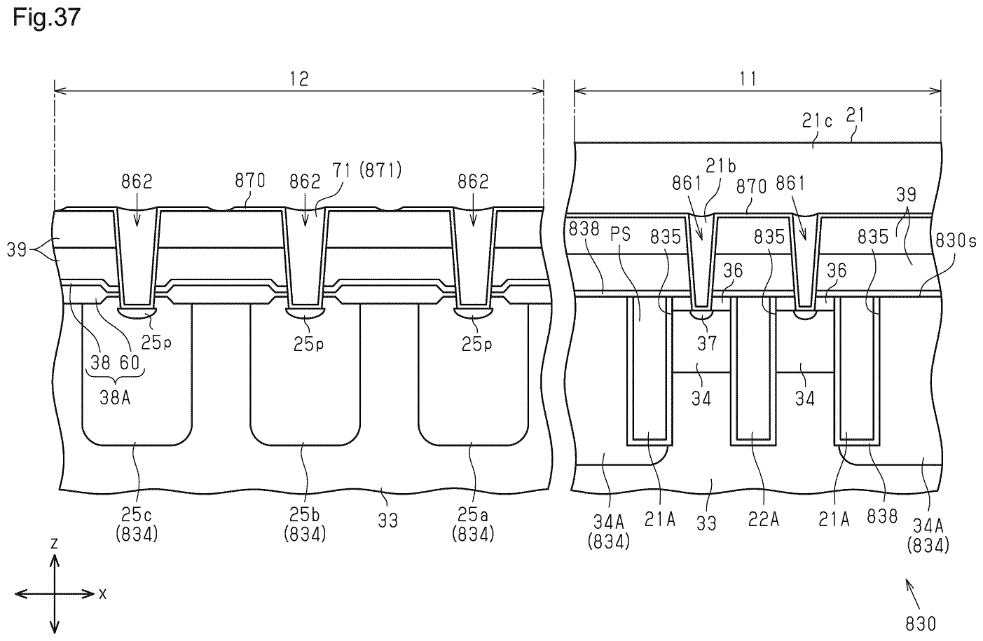

Subsequently, as illustrated in FIG. 36, a mask 890 is formed on the second electrode layer 872 in the cell region 11. That is, the second electrode layer 872 in the peripheral region 12 is exposed from the mask 890. Subsequently, as illustrated in FIG. 37, the second electrode layer 872 in the peripheral region 12 is removed through etching.

Although not illustrated, the method for manufacturing the semiconductor device according to the present embodiment includes a step of forming the barrier layer 840 in the same manner as the first embodiment. The barrier layer 840 covers the electrode main body 21c and the electrode layer 70 and the embedded electrode 71. The subsequent manufacturing steps are the same as the first embodiment.

### Advantages of Second Embodiment

In addition to the advantages of the first embodiment, the present embodiment has the following advantages.

(2-1) The thickness T10 of the electrode layer 70 is less than the thickness T5 of the barrier layer 40.

This configuration allows the steps 42 of the barrier layer 40 covering the electrode layer 70 of each of the field plates 25e to 25h to be further smaller. This further limits the formation of cracks caused by the steps 42.

(2-2) The thickness T10 of the electrode layer 70 at each of the field plates 25e to is less than 1 μm (in the present embodiment, the thickness T10 is about 100 nm).

This configuration results in the same advantage as advantage (2-1).

(2-3) The thickness T10 of the electrode layer 70 is less than the thickness T4 of the intermediate insulation film 39. With this configuration, cracking is further limited at the stepped portions of the barrier layer 40 covering the field plates 25e to 25h. This further limits the passage of external ions through the barrier layer 40 that would be caused by cracks.

(2-4) The thickness T10 of the electrode layer 70 is less than the thickness T6 of the insulation film 38A.

With this configuration, cracking is further limited at the stepped portions of the barrier layer 40 covering the field plates 25e to 25h. This further limits the passage of external ions through the barrier layer 40 that would be caused by cracks.

(2-5) The thickness T10 of the electrode layer 70 is less than the thickness T12 of the thick film portion 61 of the LOCOS oxide film 60.

With this configuration, cracking is further limited at the stepped portions of the barrier layer 40 covering the field plates 25e to 25h. This further limits the passage of external ions through the barrier layer 40 that would be caused by cracks.

### Modified Examples

The embodiments described above exemplify, without any intention to limit, applicable forms of a semiconductor device according to this disclosure. The semiconductor device in accordance with this disclosure may be modified from the embodiments described above. For example, the configuration in each of the above embodiments may be replaced, changed, or omitted in part or include an additional element. The modified examples described below may be combined as long as there is no technical contradiction. In the modified examples described hereafter, same reference characters are given to those components that are the same as the corresponding components of the above embodiments. Such components will not be described in detail.

In the first embodiment, the shape of the projection 28a of each of the field plates 25e to 25h can be changed freely. In one example, the curved surface 28c may be omitted from the projection 28a. The curved surface 28c and the inclined surface 28b may be omitted from the projection 28a. In this case, the plate main body 28 including the projection 28a will have a rectangular cross-section taken along a plane extending in the width direction of the plate main body 28 and the z-direction.

Further, the inclined surface 28b of the projection 28a does not have to be curved. The plate main body 28 at the inclined surface 28b may have a linear cross-section taken along a plane extending in the width direction and the z-direction. In this case, the plate main body 28 will have a trapezoidal cross sectional taken along a plane extending in the width direction and the z-direction.

In the first embodiment, the projections 28a of the field plates 25e to 25h are shaped when wet etching the field plates 25e to 25h. The present disclosure is, however, not limited. For example, the projections 28a of the field plates 25e to 25h may be shaped when dry etching the field plates 25e to 25h.

In the first embodiment, the thickness T1 of the projection 28a of each of the field plates 25e to 25h may be less than the thickness T4 of the intermediate insulation film 39. This configuration will further limit the formation of cracks in the stepped portions of the barrier layer 40 covering the field plates 25e to 25h and thus further limit the passage of external ions through the barrier layer 40 that would be caused by cracks.

In the first embodiment, the thickness T1 of the projection 28a of each of the field plates 25e to 25h may be less than the thickness T6 of the insulation film 38A. This configuration will further limit the formation of cracks in the stepped portions of the barrier layer 40 covering the field plates 25e to 25h and thus further limit the passage of external ions through the barrier layer 40 that would be caused by cracks.

In the first embodiment, the thickness T1 of the projection 28a of each of the field plates 25e to 25h may be equal to the thickness T5 of the barrier layer 40. The thickness T1 of the projection 28a may be less than the thickness T5 of the barrier layer 40.

In the second embodiment, the field plates 25e to 25h may be structures so that the second electrode layer 872 is formed on the electrode layer 70 and the embedded electrode 71. In this case, the second electrode layer 872 is etched so that the thickness T1 of the projection 28a, which is the distance between the head surface of the second electrode layer 872 and the head surface 39s of the intermediate insulation film 39, is less than the thickness T2 of the electrode main body 21c.

In the second embodiment, the thickness T10 of the electrode layer 70 may be equal to the thickness T5 of the barrier layer 40. The thickness T10 of the electrode layer 70 may be greater than the thickness T5 of the barrier layer 40.

In the second embodiment, the thickness T10 of the electrode layer 70 may be greater than or equal to the thickness T4 of the intermediate insulation film 39.

In the second embodiment, the thickness T10 of the electrode layer 70 may be greater than or equal to the thickness T6 of the insulation film 38A.

In each embodiment, the positional relationship between the projections 28a of the field plates 25e to 25h and the edges of the guard rings 25a to 25d can be changed freely. As viewed in the z-direction, the distal end of the projection 28a may overlap the edge of each of the guard rings 25a to 25d or be located inward from the edge of each of the guard rings 25a to 25d.

In the first embodiment, the thickness of at least one of the gate fingers 23A and 23B, the emitter extension 24, and the equipotential ring 26 may be greater than or equal to the thickness T2 of the electrode main body 21c of the emitter electrode 21.

In the second embodiment, at least one of the gate fingers 23A and 23B, the emitter extension 24, and the equipotential ring 26 may include the second electrode layer 872.

In the first embodiment, the configuration of the insulation film 38A may be changed to the stacked structure of the LOCOS oxide film 60 and the insulation film 38, which is the structure of the insulation film 38A in the second embodiment.

In the second embodiment, the configuration of the insulation film 38A may be changed to the stacked structure of the substrate-side insulation film 38B and the insulation film 38, which is the configuration of the insulation film 38A of the first embodiment.

In each embodiment, the insulation film 38 and the intermediate insulation film 39 are insulation films commonly shared by both the cell region 11 and the peripheral region 12. The present disclosure is not limited to such a structure. For example, the insulation film 38 and the intermediate insulation film 39 covering the cell region 11 may be formed separately from the insulation film 38 and the intermediate insulation film 39 covering the peripheral region 12. In this case, the insulation film 38 and the intermediate insulation film 39 covering the peripheral region 12 correspond to the peripheral insulation film.

In each of the above embodiments, the semiconductor device 10 may be a planar gate IGBT instead of a trench gate IGBT.

In each embodiment, the semiconductor device 10 has been embodied as an IGBT, but the present disclosure is not limited thereto, and the semiconductor device 10 may be, for example, a SiC metal-oxide-semiconductor field-effect transistor (SiC MOSFET) or a Si-MOSFET.

In this specification, the word “on” includes the meaning of “above” in addition to the meaning of “on” unless otherwise described in the context. Accordingly, the phrase of “A formed on B” means that A contacts B and is directly disposed on B and may also mean, as a modified example, that A is disposed above B without contacting B. Thus, the word “on” will also allow for a structure in which another member is formed between A and B.

The z-direction referred to in this specification does not necessarily have to be the vertical direction and does not necessarily have to fully coincide with the vertical direction. Accordingly, in the structures of the present disclosure, up and down in the z-direction as referred to in this specification is not limited to up and down in the vertical direction. For example, the x-direction may be the vertical direction. Alternatively, the y-direction may be the vertical direction.

In this specification, “at least one of A and B” should be understood to mean “only A, only B, or both A and B.”

### Clauses

Technical concepts that can be understood from the above embodiment and the modified examples will now be described. The reference characters used to denote elements of the embodiments are shown in parenthesis for the corresponding elements of the clauses described below. The reference characters are given as examples to aid understanding and not intended to limit elements to the elements denoted by the reference characters.

### [Clause 1]

A semiconductor device (10), including:
a cell region (11) in which cells (11A) are formed; and
a peripheral region (12) located at an outer side of the cell region (11) so as to surround the cell region (11), where:
the cell region (11) includes
   an insulation film (38, 39) covering the cells (11A), and
   an electrode portion (21) including a stacked part (21c) stacked on the insulation film (38, 39); and
the peripheral region (12) includes
   a first semiconductor layer (33) of a first conductive type,
   a second semiconductor region (25a-25d) of a second conductivity type partially formed in the first semiconductor layer (33),
   a peripheral insulation film (38A, 39) covering a head surface (30s) of the first semiconductor layer (33) and a head surface (30s) of the second semiconductor region (25a-25d), the peripheral insulation film (38A, 39) including an opening (52) exposing part of the head surface (30s) of the second semiconductor region (25a-25d),
   a peripheral electrode portion (25e-25h) including a projection (28a/74) projecting sideward from the opening (52) and stacked on the peripheral insulation film (38A, 39), the peripheral electrode portion (25e-25h) contacting a part of the head surface (30s) of the second semiconductor region (25a-25d) exposed from the opening (52),
   a barrier layer (40) that covers both the peripheral insulation film (38A, 39) and the peripheral electrode portion (25e-25h), the barrier layer (40) having a smaller diffusion coefficient than the peripheral insulation film (38A, 39), and
   a passivation film (13) stacked on the barrier layer (40) and having a larger diffusion coefficient than the barrier layer (40); and
a thickness (T2/T10) of the projection (28a/74) is less than a thickness (T1) of the stacked part (21c).

### [Clause 2]

The semiconductor device according to clause 1, where the thickness (T2/T10) of the projection (28a/74) is less than a thickness (T3) of the peripheral insulation film (38A, 39).

### [Clause 3]

The semiconductor device according to clause 1 or 2, where:
the peripheral electrode portion (25e-25h) includes an embedded electrode (27) embedded in the opening (52); and
the projection (28a) is integrated with the embedded electrode (27).

### [Clause 4]

The semiconductor device according to clause 1 or 2, where:
the peripheral electrode portion (25e-25h) includes an electrode layer (70) and an embedded electrode (71), the electrode layer (70) being formed on a head surface (39S) of the peripheral insulation film (38A, 39) and on a wall surface (52a) of the peripheral insulation film (38A, 39), the wall surface defining the opening (52), and the embedded electrode (71) being embedded in the opening (52); and
the projection (74) is formed by the electrode layer (70).

### [Clause 5]

The semiconductor device according to any one of clauses 1 to 4, where the thickness (T2/T10) of the projection (28a/74) is 2 μm or less.

### [Clause 6]

The semiconductor device according to any one of clauses 1 to 5, where the projection (28a/74) entirely covers the second semiconductor region (25a/25b/25c/25d) in a view taken in a thickness direction (z-direction) of the first semiconductor layer (33).

### [Clause 7]

The semiconductor device according to clause 6, where the projection (28a/74) includes a part extending beyond an edge of the second semiconductor region (25a/25b/25c/25d) in a view taken in the thickness direction (z-direction) of the first semiconductor layer (33).

### [Clause 8]

The semiconductor device according to clause 3, where the projection (28a) includes an inclined surface (28b) inclining so that the peripheral insulation film (38A, 39) becomes closer as a side end of the projection (28a) becomes closer.

### [Clause 9]

The semiconductor device according to clause 8, where the peripheral electrode portion (25e-25h) includes:
a head surface (25s) of the peripheral electrode portion (25e-25h), the head surface being the farthest from the peripheral insulating film (38A, 39); and
a curved surface (25c) connecting the inclined surface (25b) and the head surface (25s).

### [Clause 10]

The semiconductor device according to clause 8 or 9, where the inclined surface (28b) is curved.

### [Clause 11]

The semiconductor device according to any one of clauses 1 to 10, where a thickness (T5) of the barrier layer (40) is less than a thickness of the passivation film (13).

### [Clause 12]

The semiconductor device according to any one of clauses 1 to 11, where the thickness (T10) of the projection (74) is less than a thickness (T5) of the barrier layer (40).

### [Clause 13]

The semiconductor device according to any one of clauses 1 to 11, where a thickness (T5) of the barrier layer (40) is less than the thickness (T2) of the projection (28a).

### [Clause 14]

The semiconductor device according to any one of clauses 1 to 13, where:
the peripheral insulation film (38A, 39) is a silicon oxide film;
the passivation film (13) is an organic insulation film; and
the barrier layer (40) is a silicon nitride film.

### [Clause 15]

A semiconductor device, comprising:
a cell region (11) in which cells (11A) are formed; and
a peripheral region (12) located at an outer side of the cell region (11) so as to surround the cell region (11), where:
the cell region (11) includes
   an insulation film (38, 39) covering the cells (11A), and
   an electrode portion (21) including a stacked part (21c) stacked on the insulation film (38, 39); and
the peripheral region (12) includes
   a first semiconductor layer (33) of a first conductive type,
   a second semiconductor region (25a-25d) of a second conductivity type partially formed in the first semiconductor layer (33),
   a peripheral insulation film (38A, 39) formed of a silicon oxide film, the peripheral insulation film (38A, 39) covering a head surface (30s) of the first semiconductor layer (33) and a head surface (30s) of the second semiconductor region (25a-25d), and including an opening (52) exposing part of the head surface (30s) of the second semiconductor region (25a-25d),
   a peripheral electrode portion (25e-25h) including a projection (28a/74) projecting sideward from the opening (52) and stacked on the peripheral insulation film (38A, 39), the peripheral electrode portion (25e-25h) contacting a part of the head surface (30s) of the second semiconductor region (25a-25d) exposed from the opening (52),
   a barrier layer (40) formed of a silicon nitride film and covering both the peripheral insulation film (38A, 39) and the peripheral electrode portion (25e-25h), and
   a passivation film (13) formed of an organic insulation film, the passivation film stacked on the barrier layer (40); and
a thickness (T2/T10) of the projection (28a/74) is less than a thickness (T1) of the stacked part (21c).

### [Clause 16]

A method for manufacturing a semiconductor device (10), the semiconductor device (10) including a cell region (11), in which cells (11A) are formed, and a peripheral region (12), located at an outer side of the cell region (11) so as to surround the cell region (11), the method including:
forming an insulation film (838, 839) that covers the cells (11A) in the cell region (11);
forming an electrode portion (821, 822) including a stacked part (822) on the insulation film (838, 839);
forming a first semiconductor layer (33) of a first conductivity type in the peripheral region (12);
partially forming a second semiconductor region (25a-25d) of a second conductivity type on the first semiconductor layer (33);
forming a peripheral insulation film (38A, 39) that covers a head surface (30s) of the first semiconductor layer (33) and a head surface (30s) of the second semiconductor region (25a-25d);
forming an opening (862) in the peripheral insulation film (838B/850, 838, 839, the opening (862) exposes part of the head surface (30s) of the second semiconductor region (25a-25d));
forming a peripheral electrode portion (25e-25h) that includes a projection (28a/74) projecting sideward from the opening (862) on the peripheral insulation film (838B, 838, 839), the peripheral electrode portion (25e-25h) contacting a part of the second semiconductor region (834/25a-25d) exposed from the opening (862);
forming a barrier layer (840) that covers both the peripheral insulation film (838B/850, 838, 839) and the peripheral electrode portion (25a-25h), the barrier layer (840) having a smaller diffusion coefficient than the peripheral insulation film (838B/850, 838, 839); and
forming a passivation film (13) on the barrier layer (840), the passivation film (13) having a larger diffusion coefficient than the barrier layer (840),
where the forming a peripheral electrode portion (25a-25h) includes forming the projection (28a/74) to have a thickness (T2/T10) that is less than a thicknesses (T1) of the stacked part (822/21c).

### [Clause 17]

The method according to clause 15, where:
the forming an electrode portion (21) includes forming an electrode layer (821, 822) on both the insulation film (838, 839) and the peripheral insulation film (838B/850, 838, 839); and
the forming a peripheral electrode portion (25e-25h) includes forming the electrode layer (821, 822) so that a part formed on the peripheral insulation film (838B/850, 838, 839) has a thickness that is less than a thickness of a part formed on the insulation film (838, 839).

### [Clause 18]

The method according to clause 15, where the forming a peripheral electrode portion (25e-25h) includes:
forming a first electrode layer (870) on a head surface of the peripheral insulation film (838B/850, 838, 839) and a wall surface of the peripheral insulation film (838B, 850, 838, 839) defining the opening (862);
forming an embedded electrode (871) embedded in the opening (862) and having a thickness that is greater than that of the first electrode layer (870);
forming a second electrode layer (872) on the insulation film (838, 839), the peripheral insulation film (838B/850, 838, 839), and the embedded electrode (871); and
removing the second electrode layer (872) from the peripheral insulation film (838B/850, 838, 839) and the first electrode layer (871).

### [Clause 19]

The method according to clause 18, where:
the forming an electrode portion (21) includes
   forming a first electrode layer (870) on a wall surface of a cell opening (861) extending through the insulation film (838, 839) and a head surface of the insulation film (838, 839),
   forming an embedded electrode (871) that is embedded in the opening (861) and has a thickness that is greater than that of the first electrode layer (870), and
   forming the second electrode layer (872) on the embedded electrode (871) and the insulation film (838, 839);
the forming a first electrode layer (870) in the forming an electrode portion (21) is performed in the same step as the forming a first electrode layer (870) in the forming a peripheral electrode (25e-25h);
the forming an embedded electrode (871) in the forming an electrode portion (21) is performed in the same step as the forming an embedded electrode (871) in the forming a peripheral electrode portion (25e-25h); and
the forming the second electrode layer (872) in the forming an electrode portion (21) is performed in the same step as the forming a second electrode layer (872) in the forming a peripheral electrode (25e-25h).

### [Clause 20]

The method according to any one of clauses 16 to 19, where:
the forming a peripheral electrode portion (838B/850, 838, 839) includes
   forming a first insulation film (838B/850, 838) by thermally oxidizing both a head surface (830s) of the first semiconductor layer (33) and a head surface (830s) of the second semiconductor region (25a-25d), and
   forming a second insulation film (839) on a head surface of the first insulation film (838B, 838) through CVD; and
the forming a barrier layer (840) includes forming the barrier layer (840) on a head surface of the second insulation film (839).

### [Clause 21]

The method according to clause 20, where the forming a first insulation film (850) includes:
forming a mask (852) on part of a head surface (830s) of the first semiconductor layer (33) and a head surface (830s) of the second semiconductor region (25a-25d); and
forming a thermally oxidized film (851) by oxidizing a part of the head surface (830s) of the first semiconductor layer (33) and a part of the head surface (830s) of the second semiconductor region (25a-25d) that are exposed from the mask (852).

### [Clause 22]

The method according to clause 20, where the forming a first insulation film (838B) includes:
forming a first insulation layer (838B) by thermally oxidizing both the head surface (830s) of the first semiconductor layer (33) and the head surface (830s) of the second semiconductor region (25a-25d); and
wet etching the first insulation layer (838B) and then dry etching the first insulating layer (838B).

### [Clause 23]

A method for manufacturing a semiconductor device (10), the semiconductor device (10) including a cell region (11), in which cells (11A) are formed, and a peripheral region (12), located at an outer side of the cell region (11) so as to surround the cell region (11), the method including:
forming an insulation film (838, 839) that covers the cells (11A) in the cell region (11);
forming an electrode portion (821, 822) including a stacked part (822) on the insulation film (838, 839);
forming a first semiconductor layer (33) of a first conductivity type in the peripheral region (12);
partially forming a second semiconductor region (25a-25d) of a second conductivity type on the first semiconductor layer (33);
forming a peripheral insulation film (838B/850) with a silicon oxide film that covers a head surface (830s) of the first semiconductor layer (33) and a head surface (830s) of the second semiconductor region (25a-25d);
forming an opening (862) that exposes part of the head surface (830s) of the second semiconductor region (25a-25d) in the peripheral insulation film (838B/850, 838, 839);
forming a peripheral electrode portion (25e-25h) that includes a projection projecting sideward from the opening (862) and formed on the peripheral insulation film (838B/850, 838, 839), the peripheral electrode portion (25e-25h) contacting a part of the second semiconductor region (25a-25d) exposed from the opening (862);
forming a barrier layer (840) with a silicon nitride film that covers both the peripheral insulation film (838B/850, 838, 839) and the peripheral electrode portion (25e-25h); and
forming a passivation film (13), formed of an organic insulation film, on the barrier layer (840),
where the forming a peripheral electrode portion (25e-25h) includes forming the projection (28a/870) to have a thickness (T2/T10) that is less than a thickness (T1) of the stacked part (822/21c).

### REFERENCE SIGNS LIST

10) semiconductor device
11) cell region
11A) main cell (cell)
12) peripheral region
13) passivation film
21) emitter electrode
21c) electrode main body (stacked part)
22) gate electrode
23) gate finger
23ba) embedded electrode
23bc) projection
24) emitter extension
24a) embedded electrode
24c) projection
25) FLR
25a-25d) guard ring (second semiconductor region)
25e-25h) field plate (peripheral electrode portion)
25s) head surface
27) embedded electrode
28a) projection
28b) inclined surface
28c) curved surface
28s) head surface
30) semiconductor substrate
30s) substrate head surface (head surface of first semiconductor layer, head surface of second semiconductor region)
33) drift layer (first semiconductor layer)
34A) base region
35) trench
36) emitter region
37) base contact region
38) insulation film
38A) insulation film
39) intermediate insulation film
40) barrier layer
41) step
51) inner opening
52, 53, 54) peripheral opening (opening)
52a) wall surface
60) LOCOS oxide film
70) electrode layer
71) embedded electrode
74) projection
T1) projection thickness
T2) stacked part thickness
T3) total thickness of insulation film 38A and intermediate film 39 (peripheral insulation film thickness)
T5) barrier layer thickness
T10) electrode layer thickness

1. A semiconductor device, comprising:
a cell region in which cells are formed; and
a peripheral region located at an outer side of the cell region so as to surround the cell region, wherein:
the cell region includes
an insulation film covering the cells, and
an electrode portion including a stacked part stacked on the insulation film; and
the peripheral region includes
a first semiconductor layer of a first conductive type,
a second semiconductor region of a second conductivity type partially formed in the first semiconductor layer,
a peripheral insulation film covering a head surface of the first semiconductor layer and a head surface of the second semiconductor region, the peripheral insulation film including an opening exposing part of the head surface of the second semiconductor region,
a peripheral electrode portion including a projection projecting sideward from the opening and stacked on the peripheral insulation film, the peripheral electrode portion contacting a part of the head surface of the second semiconductor region exposed from the opening,
a barrier layer that covers both the peripheral insulation film and the peripheral electrode portion, the barrier layer having a smaller diffusion coefficient than the peripheral insulation film, and
a passivation film stacked on the barrier layer and having a larger diffusion coefficient than the barrier layer; and
a thickness of the projection is less than a thickness of the stacked part.

2. The semiconductor device according to claim 1, wherein the thickness of the projection is less than a thickness of the peripheral insulation film.

3. The semiconductor device according to claim 1, wherein:
the peripheral electrode portion includes an embedded electrode embedded in the opening; and
the projection is integrated with the embedded electrode.

4. The semiconductor device according to claim 1, wherein:
the peripheral electrode portion includes an electrode layer and an embedded electrode, the electrode layer being formed on a head surface of the peripheral insulation film and on a wall surface of the peripheral insulation film, the wall surface defining the opening, and the embedded electrode being embedded in the opening; and
the projection is formed by the electrode layer.

5. The semiconductor device according to claim 1, wherein the thickness of the projection is 2 μm or less.

6. The semiconductor device according to claim 1, wherein the projection entirely covers the second semiconductor region in a view taken in a thickness direction of the first semiconductor layer.

7. The semiconductor device according to claim 6, wherein the projection includes a part extending beyond an edge of the second semiconductor region in a view taken in the thickness direction of the first semiconductor layer.

8. The semiconductor device according to claim 3, wherein the projection includes an inclined surface inclining so that the peripheral insulation film becomes closer as a side end of the projection becomes closer.

9. The semiconductor device according to claim 8, wherein the peripheral electrode portion includes:
a head surface of the peripheral electrode portion, the head surface being the farthest from the peripheral insulating film; and
a curved surface connecting the inclined surface and the head surface.

10. The semiconductor device according to claim 8, wherein the inclined surface is curved.

11. The semiconductor device according to claim 1, wherein a thickness of the barrier layer is less than a thickness of the passivation film.

12. The semiconductor device according to claim 1, wherein the thickness of the projection is less than a thickness of the barrier layer.

13. The semiconductor device according to claim 1, wherein a thickness of the barrier layer is less than the thickness of the projection.

14. The semiconductor device according to claim 1, wherein:
the peripheral insulation film is a silicon oxide film;
the passivation film is an organic insulation film; and
the barrier layer is a silicon nitride film.

15. A semiconductor device, comprising:
a cell region in which cells are formed; and
a peripheral region located at an outer side of the cell region so as to surround the cell region, wherein:
the cell region includes
an insulation film covering the cells, and
an electrode portion including a stacked part stacked on the insulation film; and
the peripheral region includes
a first semiconductor layer of a first conductive type,
a second semiconductor region of a second conductivity type partially formed in the first semiconductor layer,
a peripheral insulation film formed of a silicon oxide film, the peripheral insulation film covering a head surface of the first semiconductor layer and a head surface of the second semiconductor region, and including an opening exposing part of the head surface of the second semiconductor region,
a peripheral electrode portion including a projection projecting sideward from the opening and stacked on the peripheral insulation film, the peripheral electrode portion contacting a part of the head surface of the second semiconductor region exposed from the opening,
a barrier layer formed of a silicon nitride film and covering both the peripheral insulation film and the peripheral electrode portion, and
a passivation film formed of an organic insulation film, the passivation film stacked on the barrier layer; and
a thickness of the projection is less than a thickness of the stacked part.
